(19) United States
(12) Patent Application Publication
(10) Pub. No.: US 2017/0115563 A1
(43) Pub. Date: Apr. 27, 2017

(54) ENERGY-SENSITIVE RESIN COMPOSITION

(71) Applicant: TOKYO OHKA KOGYO CO., LTD., Kawasaki-shi (JP)

(72) Inventors: Kunihiro NODA, Kawasaki-shi (JP); Hiroki CHISAKA, Kawasaki-shi (JP); Dai SHIOTA, Kawasaki-shi (JP)

(73) Assignee: TOKYO OHKA KOGYO CO., LTD., Kawasaki-shi (JP)

(21) Appl. No.: 15/317,015

(22) PCT Filed: Jun. 11, 2015
(86) PCT No.: PCT/JP2015/066935

§ 371 Date: Dec. 7, 2016

(30) Foreign Application Priority Data
Jun. 27, 2014 (JP) 2014-133088

(51) Int. Cl. G03F 7/004; C09D 179/04; G03F 7/038; G03F 7/40; G03F 7/16; G03F 7/20; G03F 7/38; G03F 7/32; C08G 73/22; G03F 7/039

(52) U.S. Cl. CPC G03F 7/0045; C08G 73/22; C09D 179/04; G03F 7/038; G03F 7/039; G03F 7/162; G03F 7/168; G03F 7/20; G03F 7/38; G03F 7/322; G03F 7/40

(57) ABSTRACT

An energy-sensitive resin composition that provides a highly transparent polybenzoxazole resin with suppressed coloring, which has excellent chemical resistance and excellent mechanical characteristics such as tensile elongation, even in cases where a polybenzoxazole precursor is thermally treated at low temperatures; a method for producing a polybenzoxazole film or polybenzoxazole molded body using the energy-sensitive resin composition; and a pattern forming method using the energy-sensitive resin composition. The energy-sensitive resin composition contains a polybenzoxazole precursor that is obtained by reacting an aromatic diaminediol with a diformyl compound or a dicarboxylic acid dihalide; a solvent; and a compound that is decomposed by the action of light and/or heat to generate a base and/or an acid.

### TECHNICAL FIELD

The present invention relates to an energy-sensitive resin composition containing a polybenzoxazole precursor, a method for producing a polybenzoxazole film or a polybenzoxazole molded product using the energy-sensitive resin composition; and a pattern forming method using the energy-sensitive resin composition.

### BACKGROUND ART

Since a polybenzoxazole resin has excellent heat resistance, mechanical strength, insulating properties, and dimensional stability, a polybenzoxazole resin is widely used as not only fiber or a film but also an insulating material and a protective material in electric or electronic parts such as various elements or electronic substrates including multilayer wiring substrates.

In general, a polybenzoxazole resin is formed by thermally treating a precursor polymer obtained by polymerization of an aromatic diaminediol having an amino group and a hydroxyl group on the adjacent carbon atoms in the aromatic ring and a dialdehyde compound or a dicarbonyl compound such as a dicarboxylic acid dihalide in an organic solvent such as N-methyl-2-pyrrolidone (NMP), dimethylacetamide (DMAc), or dimethylformamide (DMF) at a high temperature of about 300° C.

As a specific example of a polybenzoxazole resin produced by such a method, a polybenzoxazole resin formed by raising the temperature of a solution of a precursor polymer obtained by reacting an aromatic diaminediol having an amino group and a hydroxyl group on the adjacent carbon atoms in the aromatic ring with di(4-formylphenyl)alkane or di(4-halocarbonylphenyl)alkane in dimethylformamide from 200° C. and by finally thermally treating the solution at 300° C. is known (refer to PTL 1).

### CITATION LIST

### Patent Literature

[PTL 1] WO 2012/137840

### SUMMARY OF INVENTION

### Technical Problem

In the method in the related art as described in PTL 1, it is necessary to heat a precursor polymer at a high temperature, and in a case where a precursor polymer is heated at a low temperature below 200° C., the mechanical characteristics, chemical resistance, and transparency of the polybenzoxazole resin are significantly deteriorated.

The present invention has been made in consideration of the above problems, and an object of the present invention is to provide an energy-sensitive resin composition that provides a highly transparent polybenzoxazole resin with suppressed coloring, which has excellent mechanical characteristics such as tensile elongation and excellent chemical resistance, even in cases where a polybenzoxazole precursor is thermally treated at low temperatures; a method for producing a polybenzoxazole film or a polybenzoxazole molded product using the energy-sensitive resin composition; and a pattern forming method using the energy-sensitive resin composition.

### Solution to Problem

The present inventors repeated thorough studies to solve the above problems. As a result, the present inventors found that by adding a compound which decomposes by the action of at least one of light and heat to generate at least one of a base and an acid to a composition containing a polybenzoxazole precursor, the above problems can be solved, and completed the present invention. Specifically, the present invention provides the following.

A first aspect of the present invention is an energy-sensitive resin composition that contains a polybenzoxazole precursor that is obtained by reacting an aromatic diaminediol represented by the following formula (1) with a dicarbonyl compound represented by the following formula (2), a solvent, and a compound (A) which decomposes by the action of at least one of light and heat to generate at least one of a base and an acid.

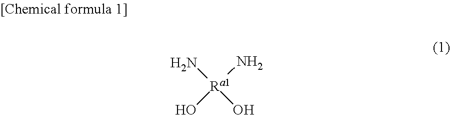

In the formula, R^{a1} is a tetravalent organic group containing one or more aromatic rings, and with respect to two pairs of combinations of an amino group and a hydroxyl group contained in the aromatic diaminediol represented by the formula (1), in each of the combinations, the amino group and the hydroxyl group are bonded to two carbon atoms adjacent to each other on the aromatic ring contained in R^{a1}.

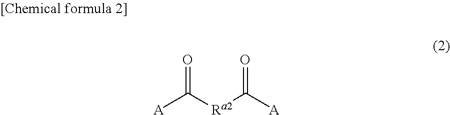

In the formula, R^{a2} represents a divalent organic group, and A represents a hydrogen atom or a halogen atom.

A second aspect of the present invention is a method for producing a polybenzoxazole film or a polybenzoxazole molded product including a forming step of forming a coating film or a molded product formed of the energy-sensitive resin composition and a decomposing step of decomposing the compound (A) in the coating film or the molded product by exposing or heating the coating film or the molded product.

A third aspect of the present invention is a pattern forming method including a forming step of forming a coating film or a molded product formed of the energy-sensitive resin composition, an exposure step of selectively exposing the coating film or the molded product, a development step of developing the coating film or the molded product after the exposing, and a heating step of heating the coating film or the molded product after the developing, in a case where the compound (A) is a compound which decomposes by the action of light at least to generate at least one of a base and an acid.

### Advantageous Effects of Invention

According to the present invention, it is possible to provide an energy-sensitive resin composition that provides a highly transparent polybenzoxazole resin with suppressed coloring, which has excellent mechanical characteristics such as tensile elongation and excellent chemical resistance, even in cases where a polybenzoxazole precursor is thermally treated at low temperatures, a method for producing a polybenzoxazole film or a polybenzoxazole molded product using the energy-sensitive resin composition, and a pattern forming method using the energy-sensitive resin composition.

### DESCRIPTION OF EMBODIMENTS

### <<Energy-Sensitive Resin Composition>>

The energy-sensitive resin composition according to the present invention contains at least a polybenzoxazole precursor that is obtained by reacting an aromatic diaminediol represented by the above formula (1) with a dicarbonyl compound represented by the above formula (2), a solvent, and a compound (A) which decomposes by the action of at least one of light and heat to generate at least one of a base and an acid.

### <Polybenzoxazole Precursor>

The polybenzoxazole precursor may be used solely or as a mixture of two or more kinds thereof. As the synthesis raw materials of the polybenzoxazole precursor, a dicarbonyl compound having a specific structure is used together with an aromatic diaminediol. Next, the aromatic diaminediol and the dicarbonyl compound will be described.

### [Aromatic Diaminediol]

In the present invention, a compound represented by the following formula (1) is used as the aromatic diaminediol. The aromatic diaminediol may be used solely or in combination of two or more kinds thereof.

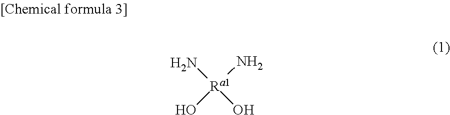

In the formula (1), R^{a1} is a tetravalent organic group containing at least one aromatic ring; and with respect to two pairs of combinations of an amino group and a hydroxyl group contained in the aromatic diaminediol represented by the formula (1), in each of the combinations, the amino group and the hydroxyl group are bonded to two carbon atoms adjacent to each other on the aromatic ring contained in R^{a1}.

In the formula (1), R^{a1} is a tetravalent organic group containing at least one aromatic ring, and the number of carbon atoms thereof is preferably 6 to 50, and more preferably 6 to 30. R^{a1} may also be an aromatic group and may be a group in which two or more aromatic groups are bonded to each other via an aliphatic hydrocarbon group or a halogenated aliphatic hydrocarbon group, or a bond containing a hetero atom, such as an oxygen atom, a sulfur atom, and a nitrogen atom. Examples of the bond containing a hetero atom, such as an oxygen atom, a sulfur atom, and a nitrogen atom, which may be contained in R^{a1}, include —CONH—, —NH—, —N═N—, —CH═N—, —COO—, —O—, —CO—, —SO—, —SO₂—, —S—, and —S—S—, with —O—, —CO—, —SO—, —SO₂—, —S—, and —S—S— being preferred.

The aromatic ring contained in R^{a1} may be an aromatic heterocyclic ring. The aromatic ring bonded to the amino group and the hydroxyl group in R^{a1} is preferably a benzene ring. In the case where the ring bonded to the amino group and the hydroxyl group in R^{a1} is a condensed ring containing two or more rings, the ring bonded to the amino group and the hydroxyl group in the condensed ring is preferably a benzene ring.

Suitable examples of R^{a1} include groups represented by the following formulae (1-1) to (1-9).

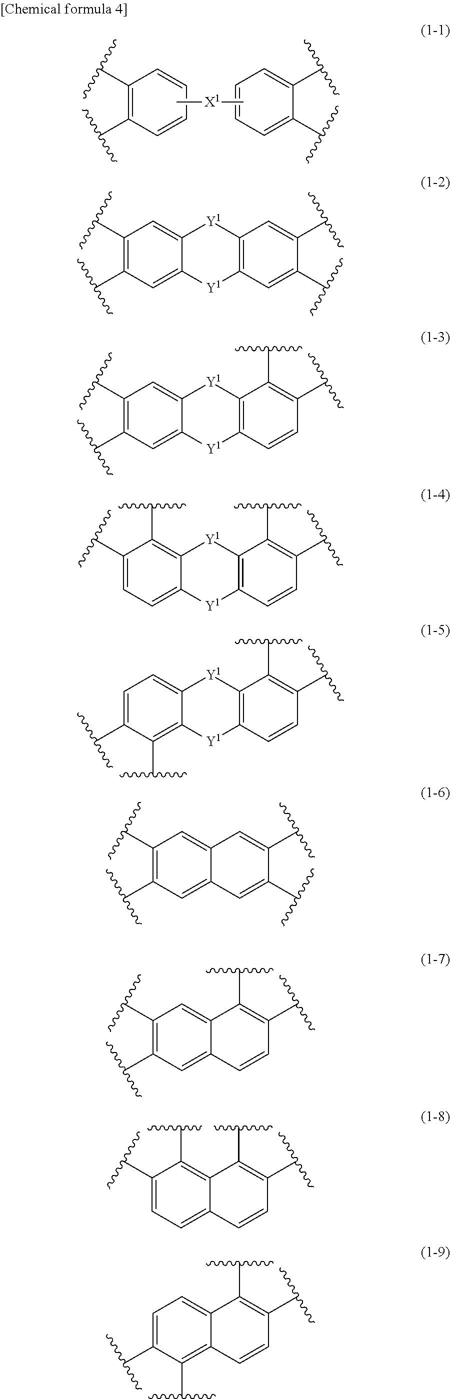

In the formula (1-1), X¹ is one member selected from the group consisting of an alkylene group having 1 to 10 carbon atoms, a fluorinated alkylene group having 1 to 10 carbon atoms, —O—, —S—, —SO—, —SO₂—, —CO—, —COO—, —CONH—, and a single bond. In the formulae (1-2) to (1-5), each Y¹ may be the same as or different from every other Y¹ and is one member selected from the group consisting of —CH₂—, —O—, —S—, —SO—, —SO₂—, —CO—, and a single bond.

Each of the groups of the foregoing formulae (1-1) to (1-9) may have one or plural substituents on the aromatic ring. As suitable examples of the substituent, a fluorine atom, an alkyl group having 1 to 6 carbon atoms, an alkoxy group having 1 to 6 carbon atoms, a fluorinated alkyl group having 1 to 6 carbon atoms, and a fluorinated alkoxy group having 1 to 6 carbon atoms are preferred. In the case where the substituent is a fluorinated alkyl group or a fluorinated alkoxy group, it is preferably a perfluoroalkyl group or a perfluoroalkoxy group.

Specific examples of the compound represented by the foregoing formula (1) include 2,4-diamino-1,5-benzenediol, 2,5-diamino-1,4-benzenediol, 2,5-diamino-3-fluoro-1,4-benzenediol, 2,5-diamino-3,6-difluoro-1,4-benzenediol, 2,6-diamino-1,5-dihydroxynaphthalene, 1,5-diamino-2,6-dihydroxynaphthalene, 2,6-diamino-3,7-dihydroxynaphthalene, 1,6-diamino-2,5-dihydroxynaphthalene, 4,4′-diamino-3,3′-dihydroxybiphenyl, 3,3′-diamino-4,4′-dihydroxybiphenyl, 2,3′-diamino-3,2′-dihydroxybiphenyl, 3,4′-diamino-4,3′-dihydroxybiphenyl, 4,4′-diamino-3,3′-dihydroxy-6,6′-ditrifluoromethylbiphenyl, 3,3′-diamino-4,4′-dihydroxy-6,6′-ditrifluoromethylbiphenyl, 2,3′-diamino-3,2′-dihydroxy-6,6′-ditrifluoromethylbiphenyl, 3,4′-diamino-4,3′-dihydroxy-6,6′-ditrifluoromethylbiphenyl, 4,4′-diamino-3,3′-dihydroxy-5,5′-ditrifluoromethylbiphenyl, 3,3′-diamino-4,4′-dihydroxy-5,5′-ditrifluoromethylbiphenyl, 2,3′-diamino-3,2′-dihydroxy-5,5′-ditrifluoromethylbiphenyl, 3,4′-diamino-4,3′-dihydroxy-5,5′-ditrifluoromethylbiphenyl, bis(4-amino-3-hydroxyphenyl)methane, bis(3-amino-4-hydroxyphenyl)methane, 3,4′-diamino-4,3′-dihydroxydiphenylmethane, bis(4-amino-3-hydroxy-6-trifluoromethyl)methane, bis(3-amino-4-hydroxy-6-trifluoromethyl)methane, 3,4′-diamino-4,3′-dihydroxy-6,6′-ditrifluoromethyldiphenyl methane, bis(4-amino-3-hydroxyphenyl)difluoromethane, bis(3-amino-4-hydroxyphenyl)difluoromethane, 3,4′-diamino-4,3′-dihydroxydiphenyldifluoromethane, bis(4-amino-3-hydroxy-6-trifluoromethylphenyl)difluoromethane, bis(3-amino-4-hydroxy-6-trifluoromethylphenyl)difluoromethane, 3,4′-diamino-4,3′-dihydroxy-6,6′-ditrifluoromethyldiphenyl difluoromethane, bis(4-amino-3-hydroxyphenyl)ether, bis(3-amino-4-hydroxyphenyl)ether, 3,4′-diamino-4,3′-dihydroxydiphenylether, bis(4-amino-3-hydroxy-6-trifluoromethylphenyl)ether, bis(3-amino-4-hydroxy-6-trifluoromethylphenyl)ether, 3,4′-diamino-4,3′-dihydroxy-6,6′-ditrifluoromethyldiphenyl ether, bis(4-amino-3-hydroxyphenyl)ketone, bis(3-amino-4-hydroxyphenyl)ketone, 3,4′-diamino-4,3′-dihydroxydiphenylketone, bis(4-amino-3-hydroxy-6-trifluoromethyl)ketone, bis(3-amino-4-hydroxy-6-trifluoromethyl)ketone, 3,4′-diamino-4,3′-dihydroxy-6,6′-ditrifluoromethyldiphenyketone, 2,2-bis(4-amino-3-hydroxyphenyl)propane, 2,2-bis(3-amino-4-hydroxyphenyl)propane, 2-(3-amino-4-hydroxyphenyl)-2-(4′-amino-3′-hydroxyphenyl)propane, 2,2-bis(4-amino-3-hydroxy-6-trifluoromethylphenyl)propane, 2,2-bis(3-amino-4-hydroxy-6-trifluoromethylphenyl)propane, 2-(3-amino-4-hydroxy-6-trifluoromethylphenyl)-2-(4′-amino-3′-hydroxy-6′-trifluoromethylphenyl)propane, 2,2-bis(3-amino-4-hydroxy-5-trifluoromethylphenyl)propane, 2,2-bis(4-amino-3-hydroxyphenyl)hexafluoropropane, 2,2-bis(3-amino-4-hydroxyphenyl)hexafluoropropane, 2-(3-amino-4-hydroxyphenyl)-2-(4′-amino-3′-hydroxyphenyl)hexafluoropropane, 2,2-bis(4-amino-3-hydroxy-6-trifluoromethylphenyl)hexafluoropropane, 2,2-bis(3-amino-4-hydroxy-6-trifluoromethylhenyl)hexafluoropropane, 2-(3-amino-4-hydroxy-6-trifluoromethylphenyl)-2-(4′-amino-3′-hydroxy-6′-trifluoromethylphenyl)hexafluoropropane, 2,2-bis(3-amino-4-hydroxy-5-trifluoromethylphenyl)hexafluoropropane, bis(4-amino-3-hydroxyphenyl)sulfone, bis(3-amino-4-hydroxyphenyl)sulfone, 3,4′-diamino-4,3′-dihydroxydiphenylsulfone, bis(4-amino-3-hydroxy-6-trifluoromethyl)sulfone, bis(3-amino-4-hydroxy-6-trifluoromethyl)sulfone, 3,4′-diamino-4,3′-dihydroxy-6,6′-ditrifluoromethyldiphenyl sulfone, bis(4-amino-3-hydroxyphenyl)sulfide, bis(3-amino-4-hydroxyphenyl)sulfide, 3,4′-diamino-4,3′-dihydroxydiphenylsulfide, bis(4-amino-3-hydroxy-6-trifluoromethyl)sulfide, bis(3-amino-4-hydroxy-6-trifluoromethyl)sulfide, 3,4′-diamino-4,3′-dihydroxy-6,6′-ditrifluoromethyldiphenyl sulfide, (4-amino-3-hydroxyphenyl)-4-amino-3-hydroxyphenylbenzoate, (3-amino-4-hydroxyphenyl)-3-amino-4-hydroxyphenylbenzoate, (3-amino-4-hydroxyphenyl)-4-amino-3-hydroxyphenylbenzoate, (4-amino-3-hydroxyphenyl)-3-amino-4-hydroxyphenylbenzoate, N-(4-amino-3-hydroxyphenyl)-4-amino-3-hydroxyphenylbenzamide, N-(3-amino-4-hydroxyphenyl)-3-amino-4-hydroxyphenylbenzamide, N-(3-amino-4-hydroxyphenyl)-4-amino-3-hydroxyphenylbenzamide, N-(4-amino-3-hydroxyphenyl)-3-amino-4-hydroxyphenylbenzamide, 2,4′-bis(4-amino-3-hydroxyphenoxy)biphenyl, 2,4′-bis(3-amino-4-hydroxyphenoxy)biphenyl, 4,4′-bis(4-amino-3-hydroxyphenoxy)biphenyl, 4,4′-bis(3-amino-4-hydroxyphenoxy)biphenyl, di[4-(4-amino-3-hydroxyphenyl)phenyl]ether, di[4-(3-amino-4-hydroxyphenoxy)phenyl]ether, 2,4′-bis(4-amino-3-hydroxyphenoxy)benzophenone, 2,4′-bis(3-amino-4-hydroxyphenoxy)benzophenone, 4,4′-bis(4-amino-3-hydroxyphenoxy)benzophenone, 4,4′-bis(3-amino-4-hydroxyphenoxy)benzophenone, 2,4′-bis(4-amino-3-hydroxyphenoxy)octafluorobiphenyl, 2,4′-bis(3-amino-4-hydroxyphenoxy)octafluorobiphenyl, 4,4′-bis(4-amino-3-hydroxyphenoxy)octafluorobiphenyl, 4,4′-bis(3-amino-4-hydroxyphenoxy)octafluorobiphenyl, 2,4′-bis(4-amino-3-hydroxyphenoxy)octafluorobenzophenone, 2,4′-bis(3-amino-4-hydroxyphenoxy)octafluorobenzophenone, 4,4′-bis(4-amino-3-hydroxyphenoxy)octafluorobenzophenone, 4,4′-bis(3-amino-4-hydroxyphenoxy)octafluorobenzophenone, 2,2-bis[4-(4-amino-3-hydroxyphenoxy)phenyl]propane, 2,2-bis[4-(3-amino-4-hydroxyphenoxy)phenyl]propane, 2,2-bis[4-(4-amino-3-hydroxyphenoxy)phenyl]hexafluoropropane, 2,2-bis[4-(3-amino-4-hydroxyphenoxy)phenyl]hexafluoropropane, 2,8-diamino-3,7-dihydroxydibenzofuran, 2,8-diamino-3,7-dihydroxyfluorene, 2,6-diamino-3,7-dihydroxyxanthene, 9,9-bis(4-amino-3-hydroxyphenyl)fluorene, and 9,9-bis(3-amino-4-hydroxyphenyl)fluorene.

Among these compounds, 2,2-bis(3-amino-4-hydroxyphenyl)hexafluoropropane is preferred from the standpoint that a polybenzoxazole resin having excellent transparency can be formed.

### [Dicarbonyl Compound]

As the synthesis raw materials of the polybenzoxazole precursor, a dicarbonyl compound represented by the following formula (2) is used together with the aromatic diaminediol as explained above. By condensing the above-described aromatic diaminediol and the dicarbonyl compound represented by the following formula (2), the polybenzoxazole precursor is obtained.

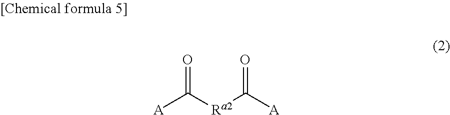

In the formula (2), R^{a2} represents a divalent organic group, and A represents a hydrogen atom or a halogen atom.

R^{2a} in the formula (2) may be an aromatic group, may be an aliphatic group, or may be a combined group of an aromatic group and an aliphatic group. R^{2a} is preferably a group containing an aromatic group and/or an alicyclic group from the standpoint that the resulting polybenzoxazole resin is favorable in heat resistance, mechanical properties, chemical resistance, and the like. The aromatic group contained in R^{2a} may be an aromatic hydrocarbon group, or may be an aromatic heterocyclic group.

R^{2a} may contain a halogen atom, an oxygen atom, a nitrogen atom, or a sulfur atom in addition to a carbon atom and a hydrogen atom. In the case where R^{2a} contains an oxygen atom, a nitrogen atom, or a sulfur atom, the oxygen atom, the nitrogen atom, or the sulfur atom may be contained in R^{2a} as a group selected from a divalent nitrogen-containing heterocyclic group, —CONH—, —NH—, —N═N—, —CH═N—, —COO—, —O—, —CO—, —SO—, —SO₂—, —S—, and —S—S—. It is more preferred that the oxygen atom, the nitrogen atom, or the sulfur atom is contained in R^{2a} as a group selected from —O—, —CO—, —SO—, —SO₂—, —S—, and —S—S—.

In the formula (2), one of the two As may be a hydrogen atom, with the other being a halogen atom; however, it is preferred that both of the two As are a hydrogen atom, or both of the two As are a halogen atom. In the case where A is a halogen atom, A is preferably chlorine, bromine, or iodine, and more preferably chlorine.

In the case of using, as the dicarbonyl compound represented by the formula (2), a dialdehyde compound in which both of the two As are a hydrogen atom, a polybenzoxazole intermediate represented by the following formula (10) is produced.

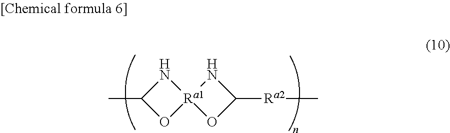

In the formula (10), R^{a1} and R^{a2} are the same as those in the formulae (1) and (2), and n is a repeating number of the unit represented by the formula (10).

In the case of using, as the dicarbonyl compound represented by the formula (2), a dicarboxylic acid dihalide in which both of the two As are a halogen atom, a polybenzoxazole intermediate represented by the following formula (20) is produced.

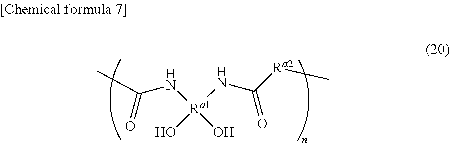

In the formula, R^{a1} and R^{a2} are the same as those in the formulae (1) and (2), and n is a repeating number of the unit represented by the formula (20).

The dialdehyde compound and the dicarboxylic acid dihalide, each of which is a suitable compound as the dicarbonyl compound, are hereunder explained.

### (Dialdehyde Compound)

The dialdehyde compound which is used as the raw material of the polybenzoxazole precursor is a compound represented by the following formula (2-1). The dialdehyde compound may be used solely or in combination of two or more kinds thereof.

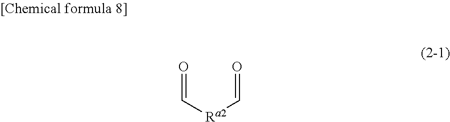

In the formula, R^{a2} is the same as that in the formula (2).

Suitable examples of the aromatic group or the aromatic ring-containing group as R^{a2} in the formula (2-1) include the following groups.

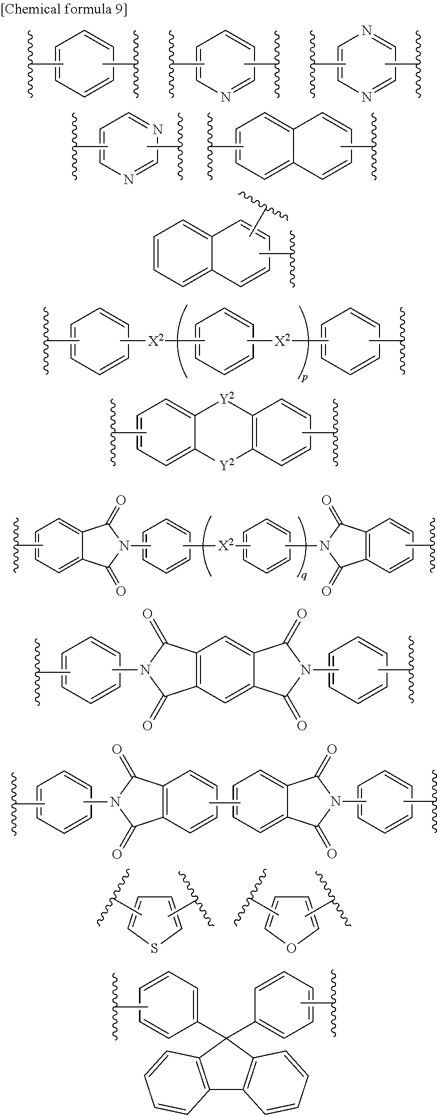

In the foregoing formulae, X² is one member selected from the group consisting of an alkylene group having 1 to 10 carbon atoms, a fluorinatedalkylene group having 1 to 10 carbon atoms, —O—, —S—, —SO—, —SO₂—, —CO—, —COO—, —CONH—, and a single bond. In the case where plural X²s are present, each of the plural X²s may be the same as or different from every other X². Each Y² may be the same as or different from every other Y² and is one member selected from the group consisting of —CH₂—, —O—, —S—, —SO—, —SO₂—, —CO—, and a single bond. Each of p and q is an integer of 0 to 3.

Suitable examples of the alicyclic group or the alicyclic ring-containing group as R^{a2} in the formula (2-1) include the following groups.

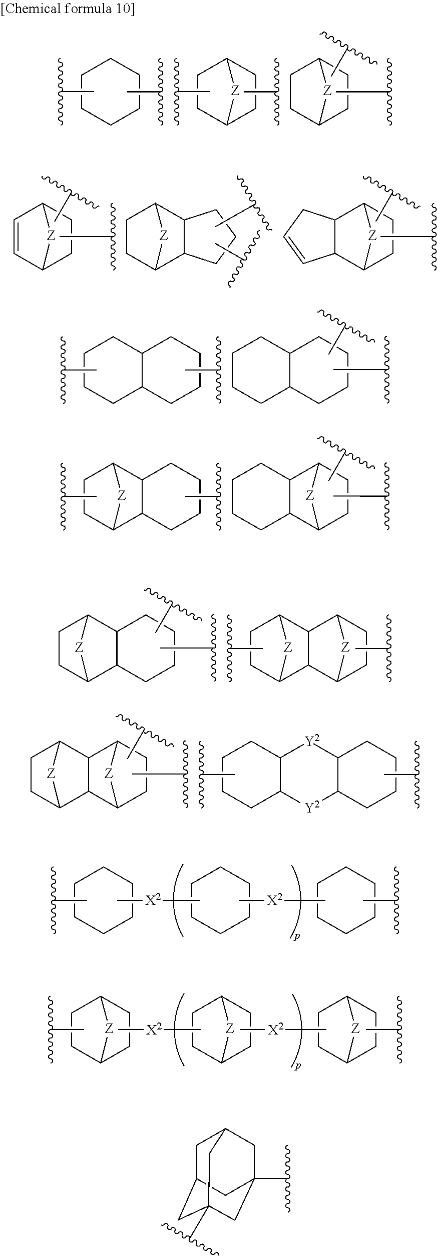

In the foregoing formulae, X² is one member selected from the group consisting of an alkylene group having 1 to 10 carbon atoms, a fluorinated alkylene group having 1 to 10 carbon atoms, —O—, —S—, —SO—, —SO₂—, —CO—, —COO—, —CONH—, and a single bond. In the case where plural X²s are present, each of the plural X²s may be the same as or different from every other X². Each Y² may be the same as or different from every other Y² and is one member selected from the group consisting of —CH₂—, —O—, —S—, —SO—, —SO₂—, —CO—, and a single bond. Z is one member selected from the group consisting of —CH₂—, —CH₂CH₂—, and —CH═CH—. Each p is an integer of 0 to 3.

The aromatic ring or the alicyclic ring contained in the suitable group as R^{a2} may have one or plural substituents on the ring. As suitable examples of the substituent, a fluorine atom, an alkyl group having 1 to 6 carbon atoms, an alkoxy group having 1 to 6 carbon atoms, a fluorinated alkyl group having 1 to 6 carbon atoms, and a fluorinated alkoxy group having 1 to 6 carbon atoms are preferred. In the case where the substituent is a fluorinated alkyl group or a fluorinated alkoxy group, it is preferably a perfluoroalkyl group or a perfluoroalkoxy group.

In the case where the dialdehyde compound represented by the formula (2-1) is an aromatic dialdehyde, suitable examples thereof include benzenedialdehydes, pyridinedialdehydes, pyrazinedialdehydes, pyrimidinedialdehydes, naphthalenedialdehydes, biphenyldialdehydes, diphenyletherdialdehydes, diphenylsulfonedialdehydes, diphenylsulfidedialdehydes, bis(formylphenoxy)benzenes, [1,4-phenylenebis(1-methylethylidene)]bisbenzaldehydes, 2,2-bis[4-(formylphenoxy)phenyl]propanes, bis[4-(formylphenoxy)phenyl]sulfides, bis[4-(formylphenoxy)phenyl]sulfones, and fluorene-containing dialdehydes.

Specific examples of the benzenedialdehydes include phthalaldehyde, isophthalaldehyde, terephthalaldehyde, 3-fluorophthalaldehyde, 4-fluorophthalaldehyde, 2-fluoroisophthalaldehyde, 4-fluoroisophthalaldehyde, 5-fluoroisophthalaldehyde, 2-fluoroterephthalaldehyde, 3-trifluoromethylphthalaldehyde, 4-trifluoromethylphthalaldehyde, 2-trifluoromethylisophthalaldehyde, 4-trifluoromethylisophthalaldehyde, 5-trifluoromethylisophthalaldehyde, 2-trifluoromethylterephthalaldehyde, 3,4,5,6-tetrafluorophthalaldehyde, 2,4,5,6-tetrafluoroisophthalaldehyde, and 2,3,5,6-tetrafluoroterephthalaldehyde.

Specific examples of the pyridinedialdehydes include pyridine-2,3-dialdehyde, pyridine-3,4-dialdehyde, and pyridine-3,5-dialdehyde.

Specific examples of the pyrazinedialdehydes include pyrazine-2,3-dialdehyde, pyrazine-2,5-dialdehyde, and pyrazine-2,6-dialdehyde.

Specific examples of the pyrimidinedialdehydes include pyrimidine-2,4-dialdehyde, pyrimidine-4,5-dialdehyde, and pyrimidine-4,6-dialdehyde.

Specific examples of the naphthalenedialdehydes include naphthalene-1,5-dialdehyde, naphthalene-1,6-dialdehyde, naphthalene-2,6-dialdehyde, naphthalene-3,7-dialdehyde, 2,3,4,6,7,8-hexafluoronaphthalene-1,5-dialdehyde, 2,3,4,5,6,8-hexafluoronaphthalene-1,6-dialdehyde, 1,3,4,5,7,8-hexafluoronaphthalene-2,6-dialdehyde, 1-trifluoromethylnaphthalne-2,6-dialdehyde, 1,5-bis(trifluoromethyl)naphthalene-2,6-dialdehyde, 1-trifluoromethylnaphthalene-3,7-dialdehyde, 1,5-bis(trifluoromethyl)naphthalene-3,7-dialdehyde, 1-trifluoromethyl-2,4,5,6,8-pentafluoronaphthalene-3,7-dialdehyde, 1-bis(trifluoromethyl)methoxy-2,4,5,6,8-pentafluoronaphthalene-3,7-dialdehyde, 1,5-bis(trifluoromethyl)-2,4,6,8-tetrafluoronaphthalene-3,7-dialdehyde, and 1,5-bis[bis(trifluoromethyl)methoxy]-2,4,6,8-tetrafluoronaphthalene-3,7-dialdehyde.

Specific examples of the biphenyldialdehydes include biphenyl-2,2′-dialdehyde, biphenyl-2,4′-dialdehyde, biphenyl-3,3′-dialdehyde, biphenyl-4,4′-dialdehyde, 6,6′-difluorobiphenyl-3,4′-dialdehyde, 6,6′-difluorobiphenyl-2,4′-dialdehyde, 6,6′-difluorobiphenyl-3,3′-dialdehyde, 6,6′-difluorobiphenyl-4,4′-dialdehyde, 6,6′-ditrifluoromethylbiphenyl-2,2′-dialdehyde, 6,6′-ditrifluoromethylbiphenyl-2,4′-dialdehyde, 6,6′-ditrifluoromethylbiphenyl-3,3′-dialdehyde, 6,6′-ditrifluoromethylbiphenyl-3,4′-dialdehyde, and 6,6′-ditrifluoromethylbiphenyl-4,4′-dialdehyde.

Specific examples of the diphenyletherdialdehydes include diphenylether-2,4′-dialdehyde, diphenylether-3,3′-dialdehyde, diphenylether-3,4′-dialdehyde, and diphenylether-4,4′-dialdehyde.

Specific examples of the diphenylsulfonedialdehydes include diphenylsulfone-3,3′-dialdehyde, diphenylsulfone-3,4′-dialdehyde, and diphenylsulfone-4,4′-dialdehyde.

Specific examples of the diphenylsulfidedialdehydes include diphenylsulfide-3,3′-dialdehyde, diphenylsulfide-3,4′-dialdehyde, and diphenylsulfide-4,4′-dialdehyde.

Specific examples of the diphenylketonedialdehydes include diphenylketone-3,3′-dialdehyde, diphenylketone-3,4′-dialdehyde, and diphenylketone-4,4′-dialdehyde.

Specific examples of the bis(formylphenoxy)benzenes include benzene-1,3-bis(3-formylphenoxy)benzene, 1,4-bis(3-formylphenoxy)benzene, and 1,4-bis(4-formylphenoxy)benzene.

Specific examples of the [1,4-phenylenebis(1-methylethylidene)]bisbenzaldehydes include 3,3′-[1,4-phenylenebis(1-methylethylidene)]bisbenzaldehyde, 3,4′-[1,4-phenylenebis(1-methylethylidene)]bisbenzaldehyde, and 4,4′-[1,4-phenylenebis(1-methylethylidene)]bisbenzaldehyde

Specific examples of the 2,2-bis[4-(formylphenoxy)phenyl]propanes include 2,2-bis[4-(2-formylphenoxy)phenyl]propane, 2,2-bis[4-(3-formylphenoxy)phenyl]propane, 2,2-bis[4-(4-formylphenoxy)phenyl]propane, 2,2-bis[4-(3-formylphenoxy)phenyl]hexafluoropropane, and 2,2-bis[4-(4-formylphenoxy)phenyl]hexafluoropropane.

Specific examples of the bis[4-(formylphenoxy)phenyl]sulfides include bis[4-(3-formylphenoxy)phenyl]sulfide and bis[4-(4-formylphenoxy)phenyl]sulfide.

Specific examples of the bis[4-(formylphenoxy)phenyl]sulfones include bis[4-(3-formylphenoxy)phenyl]sulfone and bis[4-(4-formylphenoxy)phenyl]sulfone.

Specific examples of the fluorene-containing dialdehydes include fluorene-2,6-dialdehyde, fluoroene-2,7-dialdehyde, dibenzofuran-3,7-dialdehyde, 9,9-bis(4-formylphenyl)fluorene, 9,9-bis(3-formylphenyl)fluorene, and 9-(3-formylphenyl)-9-(4′-formylphenyl)fluorene.

In addition, diphenylalkanedialdehydes or diphenylfluoroalkane dialdehydes represented by the following formulae can also be suitably used as the aromatic dialdehyde compound.

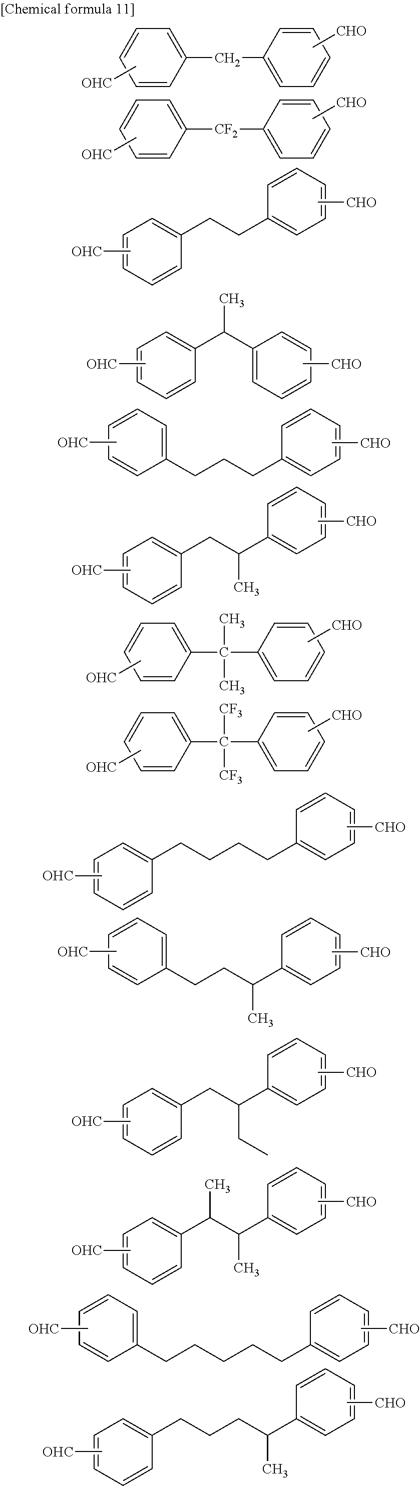

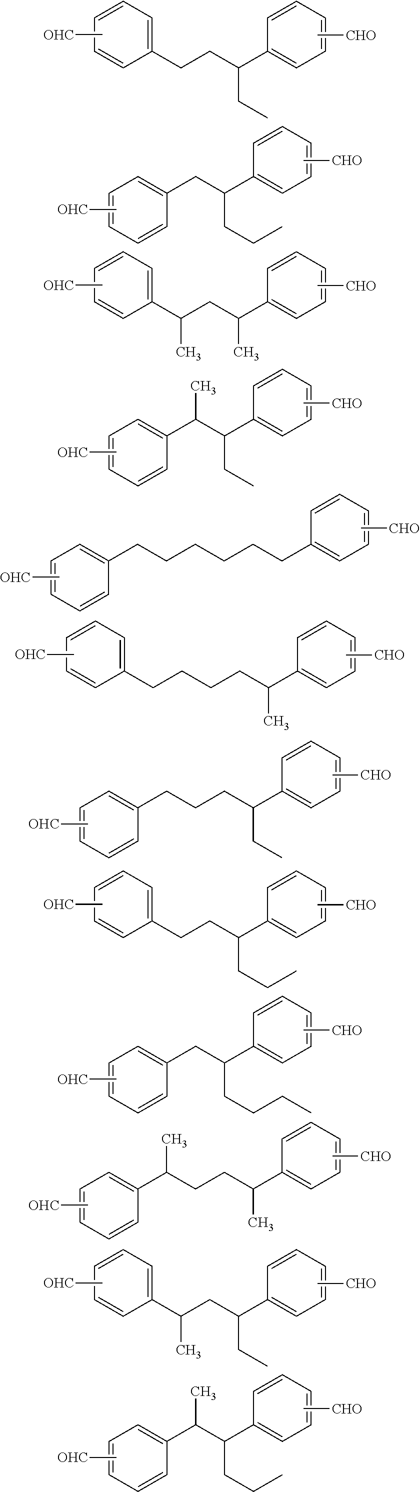

Furthermore, imide bond-containing compounds represented by the following formulae can also be suitably used as the aromatic dialdehyde compound.

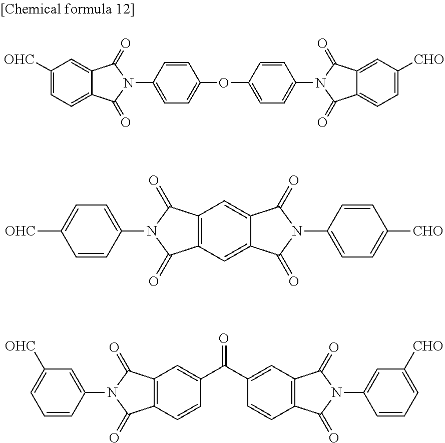 [SMILES: O=Cc1ccc2c(c1)C(=O)N(c1ccc(Oc3ccc(N4C(=O)c5ccc(C=O)cc5C4=O)cc3)cc1)C2=O ; O=Cc1ccc(-n2c(=O)c3cc4c(=O)n(-c5ccc(C=O)cc5)c(=O)c4cc3c2=O)cc1 ; O=Cc1cccc(N2C(=O)c3ccc(C(=O)c4ccc5c(c4)C(=O)N(c4cccc(C=O)c4)C5=O)cc3C2=O)c1]

In the case where the dicarbonyl compound represented by the formula (2-1) is an alicyclic group-containing alicyclic dialdehyde, suitable examples thereof include cyclohexane-1,4-dialdehyde, cyclohexane-1,3-dialdehyde, bicyclo[2.2.1]heptane-2,5-dialdehyde, bicyclo[2.2.2]octane-2,5-dialdehyde, bicyclo[2.2.2]oct-7-ene-2,5-dialdehyde, bicyclo[2.2.1]heptane-2,3-dialdehyde, bicyclo[2.2.1]hept-5-ene-2,3-dialdehyde, tricyclo[5.2.1.0^{2,6}]decane-3,4-dialdehyde, tricyclo[5.2.1.0^{2,6}]dec-4-ene-8,9-dialdehyde, perhydronaphthalene-2,3-dialdehyde, perhydronaphthalene-1,4-dialdehyde, perhydronaphthalene-1,6-dialdehyde, perhydro-1,4-methanonaphthalene-2,3-dialdehyde, perhydro-1,4-methanonaphthalene-2,7-dialdehyde, perhydro-1,4-methanonaphthalene-7,8-dialdehyde, perhydro-1,4:5,8-dimethanonaphthalene-2,3-dialdehyde, perhydro-1,4:5,8-dimethanonaphthalene-2,7-dialdehyde, perhydro-1,4:5,8:9,10-trimethanoanthracene-2,3-dialdehyde, bicyclohexyl-4,4′-dialdehyde, dicyclohexylether-3,4′-dialdehyde, dicyclohexylmethane-3,3′-dialdehyde, dicyclohexylmethane-3,4′-dialdehyde, dicyclohexylmethane-4,4′-dialdehyde, dicyclohexyldifluoromethane-3,3′-dialdehyde, dicyclohexyldifluoromethane-3,4′-dialdehyde, dicyclohexyldifluoromethane-4,4′-dialdehyde, dicyclohexylsulfone-3,3′-dialdehyde, dicyclohexylsulfone-3,4′-dialdehyde, dicyclohexylsulfone-4,4′-dialdehyde, dicyclohexylsulfide-3,3′-dialdehyde, dicyclohexylsulfide-3,4′-dialdehyde, dicyclohexylsulfide-4,4′-dialdehyde, dicyclohexylketone-3,3′-dialdehyde, dicyclohexylketone-3,4′-dialdehyde, dicyclohexylketone-4,4′-dialdehyde, 2,2-bis(3-formylcyclohexyl)propane, 2,2-bis(4-formylcyclohexyl)propane, 2,2-bis(3-formylcyclohexyl)hexafluoropropane, 2,2-bis(4-formylcyclohexyl)hexafluoropropane, 1,3-bis(3-formylcyclohexyl)benzene, 1,4-bis(3-formylcyclohexyl)benzene, 1,4-bis(4-formylcyclohexyl)benzene, 3,3′-[1,4-cyclohexylenebis(1-methylethylidene)]biscyclohex anecarbaldehyde, 3,4′-[1,4-cyclohexylenebis(1-methylethylidene)]biscyclohex anecarbaldehyde, 4,4′-[1,4-cyclohexylenebis(1-methylethylidene)]biscyclohex anecarbaldehyde, 2,2-bis[4-(3-formylcyclohexyl)cyclohexyl]propane, 2,2-bis[4-(4-formylcyclohexyl)cyclohexyl]propane, 2,2-bis[4-(3-formylcyclohexyl)cyclohexyl]hexafluoropropane, 2,2-bis[4-(4-formylphenoxy)cyclohexyl]hexafluoropropane, bis[4-(3-formylcyclohexyloxy)cyclohexyl]sulfide, bis[4-(4-formylcyclohexyloxy)cyclohexyl]sulfide, bis[4-(3-formylcyclohexyloxy)cyclohexyl]sulfone, bis[4-(4-formylcyclohexyloxy)cyclohexyl]sulfone, 2,2′-bicyclo[2.2.1]heptane-5,6′-dialdehyde, 2,2′-bicyclo[2.2.1]heptane-6,6′-dialdehyde, and 1,3-diformyladamantane.

Among the dialdehyde compounds as explained above, isophthalaldehyde is preferred in view of the facts that it is easily synthesized or available, and that a polybenzoxazole resin having excellent heat resistance and mechanical properties is readily obtained.

### (Dicarboxylic Acid Dihalide)

The dicarboxylic acid dihalide which is used as the raw material of the polybenzoxazole precursor is a compound represented by the following formula (2-2). The dicarboxylic acid dihalide may be used solely or in combination of two or more kinds thereof.

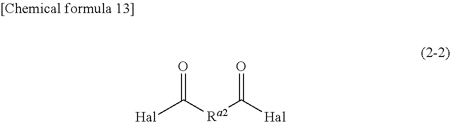

In the formula, R^{a2} is the same as that in the formula (2), and Hal is a halogen atom.

In the formula (2-2), Hal is preferably chlorine, bromine, or iodine, and more preferably chlorine.

Suitable examples of the compound represented by the formula (2-2) include the compounds described above as suitable examples of the dialdehyde compound, in which, however, the two aldehyde groups thereof are substituted with a halocarbonyl group, and preferably a chlorocarbonyl group.

Among the dicarboxylic acid dihalides as explained above, terephthalic acid dichloride is preferred in view of the facts that it is easily synthesized or available, and that a polybenzoxazole resin having excellent heat resistance and mechanical properties is readily obtained.

### [Production Method of Polybenzoxazole Precursor]

In the present invention, the polybenzoxazole precursor is produced by reacting an aromatic diaminediol described above with a dicarbonyl compound in a solvent according to a known method. As typical examples of the production method of a polybenzoxazole precursor, a production method in a case where the dicarbonyl compound is a dialdehyde compound and a production method in a case where the dicarbonyl compound is a dicarboxylic acid halide will be described below.

### [Reaction Between Aromatic Diaminediol and Dialdehyde Compound]

The reaction between the aromatic diaminediol and the dialdehyde compound is conducted in a solvent. The reaction between the aromatic diaminediol and the dialdehyde compound is a Schiff base-forming reaction and can be conducted according to a well-known method. Although a reaction temperature is not particularly limited, in general, it is preferably 20 to 200° C., more preferably 20 to 160° C., and especially preferably 100 to 160° C.

The reaction between the aromatic diaminediol and the dialdehyde compound may also be conducted by adding an entrainer to the solvent, while undergoing reflux dehydration. The entrainer is not particularly limited, and it is properly selected among organic solvents capable of forming an azeotropic mixture together with water and forming a two-phase system with water at room temperature. Suitable examples of the entrainer include esters, such as isobutyl acetate, allyl acetate, n-propyl propionate, isopropyl propionate, n-butyl propionate, and isobutyl propionate; ethers, such as dichloromethyl ether and ethyl isoamyl ether; ketones, such as ethyl propyl ketone; and aromatic hydrocarbons, such as toluene.

Although a reaction time between the aromatic diaminediol and the dialdehyde compound is not particularly limited, typically, it is preferably about 2 to 72 hours.

In producing the polybenzoxazole precursor, a use amount of the dialdehyde compound is preferably 0.5 to 1.5 moles, and more preferably 0.7 to 1.3 moles per mole of the aromatic diaminediol.

A use amount of the solvent is not particularly limited so long as the reaction between the aromatic diaminediol and the dialdehyde compound is advanced favorably. Typically, the solvent is used in an amount of 1 to 40 times by mass, and preferably 1.5 to 20 times by mass relative to a total sum of the mass of the aromatic diaminediol and the dialdehyde compound.

The reaction between the aromatic diaminediol and the dialdehyde compound is preferably conducted such that a number average molecular weight of the polybenzoxazole precursor formed reaches 1,000 to 20,000, and preferably 1,200 to 5,000.

### [Reaction Between Aromatic Diaminediol and Dicarboxylic Acid Dihalide]

The reaction between the aromatic diaminediol and the dicarboxylic acid dihalide is conducted in a solvent. Although a reaction temperature is not particularly limited, in general, it is preferably −20 to 150° C., more preferably −10 to 150° C., and especially preferably −5 to 70° C. In the reaction between the aromatic diaminediol and the dicarboxylic acid dihalide, a hydrogen halide is formed as a by-product. In order to neutralize such a hydrogen halide, a small amount of an organic base, such as triethylamine, pyridine, and N,N-dimethyl-4-aminopyridine, or an alkali metal hydroxide, such as sodium hydroxide and potassium hydroxide, may be added in the reaction liquid.

Although a reaction time between the aromatic diaminediol and the dicarboxylic acid dihalide is not particularly limited, typically, it is preferably about 2 to 72 hours.

In producing the polybenzoxazole precursor, a use amount of the dicarboxylic acid dihalide is preferably 0.5 to 1.5 moles, and more preferably 0.7 to 1.3 moles per mole of the aromatic diaminediol.

A use amount of the solvent is not particularly limited so long as the reaction between the aromatic diaminediol and the dicarboxylic acid dihalide is advanced favorably. Typically, the solvent is used in an amount of 1 to 40 times by mass, and preferably 1.5 to 20 times by mass relative to a total sum of the mass of the aromatic diaminediol and the dicarboxylic acid dihalide.

The reaction between the aromatic diaminediol and the dicarboxylic acid dihalide is conducted such that a number average molecular weight of the polybenzoxazole precursor formed reaches 1,000 to 20,000, and preferably 1,200 to 5,000.

A solution of the polybenzoxazole precursor is obtained by each of the methods as described above. In the case of forming the energy-sensitive resin composition, the solution of the polybenzoxazole precursor can be used as it is. In addition, a paste or solid of the polybenzoxazole precursor which is obtained by removing at least a part of the solvent from the solution of the polybenzoxazole precursor under reduced pressure at a low temperature to such an extent that conversion of the polybenzoxazole precursor into the polybenzoxazole resin is not caused, can also be used. In addition, a solution of the polybenzoxazole precursor, in which a solid content concentration is adjusted by adding an appropriate amount of a solvent or the like to the solution of the polybenzoxazole precursor obtained by each of the reactions as described above, can also be used for the preparation of the energy-sensitive resin composition according to the present invention.

Examples of the organic solvent used for the reaction of tetracarboxylic dianhydride and diamine include nitrogen-containing polar solvents such as N-methyl-2-pyrrolidone, N,N-dimethylacetamide, N,N-diethyl acetamide, N,N-dimethylformamide, N,N-diethylformamide, N,N,2-trimethylpropionamide, N-methylcaprolactam and N,N,N′,N′-tetramethyl urea, etc.; lactone-based polar solvents such as β-propiolactone, γ-butyrolactone, γ-valerolactone, δ-valerolactone, γ-caprolactone and ε-caprolactone, etc.; dimethyl sulfoxide; acetonitrile; fatty acid esters such as ethyl lactate and butyl lactate, etc.; and ethers such as diethyleneglycol dimethyl ether, diethyleneglycol diethyl ether, dioxane, tetrahydrofuran, methyl cellosolve acetate and ethyl cellosolve acetate, etc.

Among these organic solvents, preferred are nitrogen-containing polar solvents including N-methyl-2-pyrrolidone, N,N-dimethylacetamide, N,N-diethyl acetamide, N,N-dimethylformamide, N,N-diethylformamide, N,N,2-trimethylpropionamide, N-methylcaprolactam and N,N,N′,N′-tetramethylurea, etc. for solubilities of the resulting polybenzoxazole precursor or polybenzoxazole resin.

### Solvent

The energy-sensitive resin composition according to the present invention comprises a solvent from the perspective of application characteristics and may be in a state of a paste containing a solid or in a state of a solution, and preferably in a state of a solution. The solvent may be used alone or in combination of two or more. There is no particular limitation for the type of solvent as long as it does not inhibit the object of the present invention. Preferred examples of the solvent are the same as the examples of the solvent used in the reaction between the aromatic diaminediol and the dicarbonyl compound. The solvent may include an alcohol solvent such as polyethylene glycol, ethylene glycol, diethylene glycol, propylene glycol, and dipropylene glycol, etc. When the solvent includes an alcohol-based solvent, a pattern which is excellent in heat resistance is likely to be formed.

The content of a solvent in the energy-sensitive resin composition is not particularly limited, as long as the object of the present invention is not inhibited. The content of a solvent in the energy-sensitive resin composition is appropriately adjusted depending upon the solid content in the energy-sensitive resin composition. The solid content of the energy-sensitive resin composition is preferably 5% by mass to 70% by mass, and more preferably 10% by mass to 60% by mass.

Compound (A) which Decomposes by the Action of at Least One of Light and Heat to Generate at Least One of a Base and an Acid

The energy-sensitive resin composition according to the present invention comprises a compound (A) which decomposes by the action of at least one of light and heat to generate at least one of a base and an acid. The compound (A) can be used either alone or in combination of two or more.

By exposing or heating the energy-sensitive resin composition according to the present invention, the compound (A) in the energy-sensitive resin composition decomposes, and due to this, at least one of a base and an acid is generated. The base or the acid generated in this manner acts on the polybenzoxazole precursor in the energy-sensitive resin composition, and due to this, the conversion into the polybenzoxazole resin is accelerated. Even in a case where a polybenzoxazole precursor is thermally treated at low temperatures, since the energy-sensitive resin composition contains the compound (A), the energy-sensitive resin composition can provide a polybenzoxazole resin in which deterioration of transparency due to coloring of the resin when heating the polybenzoxazole precursor is suppressed and which has excellent mechanical characteristics such as tensile elongation and excellent chemical resistance.

In addition, since the energy-sensitive resin composition according to the present invention contains the compound (A), in a case where a polybenzoxazole resin is produced by heating the energy-sensitive resin composition, an occurrence of defects such as blister, crack, and foam on the surface of the polybenzoxazole resin can be suppressed. Therefore, in a case where a film of a polybenzoxazole resin is produced by heating a film formed of the energy-sensitive resin composition, a film having excellent appearance without defects such as crack, blister, pinholes is easily produced.

The compound (A) is preferably a compound which decomposes at 120 to 180° C. to generate a base. Such a compound (A) decomposes by heating and thereby generates a base, even when it is heated at a low temperature, such as 220° C. or lower, as long as the heating temperature is equal to or higher than its decomposition temperature. Therefore, when an energy-sensitive resin composition comprising such a compound (A) is heated to a temperature high than the decomposition temperature of the compound (A), even if the heating temperature is low, for instance, 220° C. or lower, the conversion of the polybenzoxazole precursor into the polybenzoxazole resin in the energy-sensitive resin composition is accelerated by the base which is generated by the decomposition of the compound (A), and the conversion into the polybenzoxazole resin proceeds by heating itself. As a result, the polybenzoxazole resin is formed. Since the compound (A) is sufficiently decomposed by the heating described above, an amount of the compound (A) remaining in the resulting polybenzoxazole resin is suppressed to be low. Therefore, when the polybenzoxazole resin is heated to a high temperature of, for instance, 300° C. or higher, a reduction in the weight due to the decomposition of the compound (A) is suppressed, which results in excellent heat resistance.

Further, a compound (A) is preferably such a compound which decomposes by the action of light at least to generate at least one of a base and an acid. In exposing an energy-sensitive resin composition comprising such a compound (A), the compound (A) decomposes in the exposed portions to thereby generate at least one of a base and an acid. The conversion of the polybenzoxazole precursor into the polybenzoxazole resin in the energy-sensitive resin composition is accelerated by the base or acid generated in this way so that the exposed portion becomes insoluble in the developing solution. Meanwhile, since the unexposed portion is soluble in the developing solution, it can be removed by dissolving such part in the developing solution. Therefore, it is possible to form a desired pattern by selectively exposing the energy-sensitive resin composition.

Examples of compound (A) include, for instance, a compound (A-1) which decomposes by the action of at least one of light and heat to generate an imidazole compound, and an oxime ester compound (A-2). Next, the compounds (A-1) and (A-2) will be explained.

[Compound (A-1) which Decomposes by the Action of at Least One of Light and Heat to Generate an Imidazole Compound]

An imidazole compound which the compound (A-1) generates accelerates the conversion of the polybenzoxazole precursor into the polybenzoxazole resin in the energy-sensitive resin composition according to the present invention. The imidazole compound which the compound (A-1) generates may be imidazole or an imidazole compound where a part or all of the hydrogen atoms bound to the carbon atoms in the imidazole are replaced with a substituent (s). The imidazole compound represented by the following formula (3) is preferred.

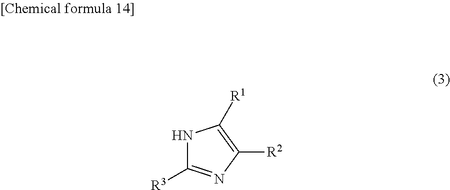

In the formula, R¹, R² and R³ each independently represent a hydrogen atom, a halogen atom, a hydroxyl group, a mercapto group, a sulfide group, a silyl group, a silanol group, a nitro group, a nitroso group, a sulfonato group, a phosphino group, a phosphinyl group, a phosphonato group, or an organic group.

As the organic group in R¹, R², and R³, an alkyl group, an alkenyl group, a cycloalkyl group, a cycloalkenyl group, an aryl group, an aralkyl group, and the like can be exemplified. The organic group may include a hetero atom. In addition, the organic group can be either a straight chain, a branched chain, or cyclic. This organic group is generally monovalent; however, can also be an organic group of divalent or more in a case of forming a cyclic structure or the like.

R¹ and R² can bind to form a cyclic structure, which may further include a bond of a hetero atom. As the cyclic structure, a heterocycloalkyl group, a heteroaryl group and the like can be exemplified, and the cyclic structure can also be a condensed ring.

In the case where the organic group represented by R¹, R², or R³ includes a hetero atom, examples of the hetero atom include an oxygen atom, a nitrogen atom, and a silicon atom. Specific examples of the bond including a hetero atom include an ether bond, a thioether bond, a carbonyl bond, a thiocarbonyl bond, an ester bond, an amide bond, a urethane bond, an imino bond (—N═C(—R)— or —C(═NR)—: R representing a hydrogen atom or an organic group, the same applies below), a carbonate bond, a sulfonyl bond, a sulfinyl bond, an azo bond and the like. Inter alia, from the viewpoint of thermal resistance of the imidazole compound, an ether bond, a thioether bond, a carbonyl bond, a thiocarbonyl bond, an ester bond, an amide bond, a urethane bond, an imino bond, a carbonate bond, a sulfonyl bond, and a sulfinyl bond are preferable.

A hydrogen atom(s) included in the groups other the organic groups represented by R¹, R², or R³ may be substituted with a hydrocarbon group(s). This hydrocarbon group can be either a straight chain, a branched chain, or cyclic.

As R¹, R², and R³, each independently, a hydrogen atom, an alkyl group having 1 to 12 carbon atoms, an aryl group having 1 to 12 carbon atoms, an alkoxy group having 1 to 12 carbon atoms, and a halogen atom are preferable, and a hydrogen atom is more preferable. Since the imidazole compound where all of R¹, R², and R³ are each a hydrogen atom has a simple structure with a small steric hindrance, such an imidazole compound can easily act on the polybenzoxazole precursor.

The compound (A-1) is not particularly limited, as long as the compound (A-1) decomposes by the action of at least one of light and heat to generate an imidazole compound, and preferred examples thereof include an imidazole compound represented by the above formula (3). Compounds which can be used as compound (A-1) are obtained by replacing the skeleton originating from amines which are generated upon exposure from the compounds which are conventionally contained in photosensitive resin compositions and generate amines by the action of light, with the skeleton originating from the imidazole compounds, preferably the imidazole compounds represented by the above formula (3).

Examples of the preferred component (A-1) include the compounds represented by the following formula (4).

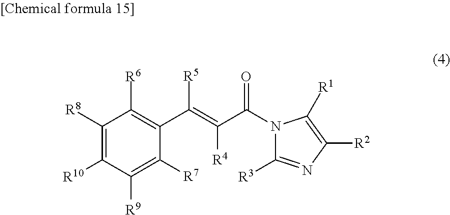

In the formula, R¹, R², and R³ each independently represent a hydrogen atom, a halogen atom, a hydroxyl group, a mercapto group, a sulfide group, a silyl group, a silanol group, a nitro group, a nitroso group, a phosphino group, a sulfonato group, a phosphinyl group, a phosphonato group, or an organic group; R⁴ and R⁵ each independently represent a hydrogen atom, a halogen atom, a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, or an organic group; R⁶, R⁷, R⁸, R⁹ and R¹⁰ each independently represent a hydrogen atom, a halogen atom, a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, an amino group, an ammonio group, or an organic group; and two or more of R⁶, R⁷, R⁸, R⁹ and R¹⁰ may join together to form a cyclic structure, which may include a bond of a hetero atom.

In the formula (4), R¹, R², and R³ are the same as those explained regarding the formula (3).

In the formula (4), as the organic group represented by R⁴ and R⁵, those listed for R¹, R², and R³ can be exemplified. This organic group can include a hetero atom, as in the case of R¹, R², and R³. Further, the organic group can be either a straight chain, a branched chain, or cyclic.

R⁴ and R⁵ are preferably, respectively independently a hydrogen atom, an alkyl group having 1 to 10 carbon atoms, a cycloalkyl group having 4 to 13 carbon atoms, a cycloalkenyl group having 4 to 13 carbon atoms, an aryloxyalkyl group having 7 to 16 carbon atoms, an aralkyl group having 7 to 20 carbon atoms, an alkyl group having 2 to 11 carbon atoms substituted with a cyano group, an alkyl group having 1 to 10 carbon atoms substituted with a hydroxyl group, an alkoxy group having 1 to 10 carbon atoms, an amido group having 2 to 11 carbon atoms, an alkylthio group having 1 to 10 carbon atoms, an acyl group having 1 to 10 carbon atoms, an ester group (—COOR, —OCOR: R representing a hydrocarbon group) having 2 to 11 carbon atoms, an aryl group having 6 to 20 carbon atoms, an aryl group having 6 to 20 carbon atoms substituted with an electron donating group and/or an electron withdrawing group, a benzyl group substituted with an electron-donating group and/or an electron withdrawing group, a cyano group, and amethylthio group. More preferably, R⁴ and R⁵ are both hydrogen atoms; or R⁴ is a methyl group and R⁵ is a hydrogen atom.

In the formula (4), as the organic group in R⁶, R⁷, R⁸, R⁹ or R¹⁰, those listed for R¹, R², and R³ can be exemplified. As in the case of R¹ and R², this organic group can include a hetero atom. Further, this organic group can be either a straight chain, a branched chain, or cyclic.

At least two of R⁶, R⁷, R⁸, R⁹ and R¹⁰ can bind to form a cyclic structure, which may further include a bond of a hetero atom. As the cyclic structure, a heterocycloalkyl group, a heteroaryl group and the like can be exemplified, and the cyclic structure can also be a condensed ring. For example, two or more of R⁶, R⁷, R⁸, R⁹ and R¹⁰ join together to form a condensed ring such as naphthalene, anthracene, phenanthrene and indene by sharing the atoms of the benzene ring to which R⁶, R⁷, R⁸, R⁹ and R¹⁰ are attached.

It is preferred that R⁶, R⁷, R⁸, R⁹ and R¹⁰ each independently a hydrogen atom, an alkyl group having 1 to 10 carbon atoms, a cycloalkyl group having 4 to 13 carbon atoms, a cycloalkenyl group having 4 to 13 carbon atoms, an aryloxyalkyl group having 7 to 16 carbon atoms, an aralkyl group having 7 to 20 carbon atoms, an alkyl group having 2 to 11 carbon atoms substituted with a cyano group, an alkyl group having 1 to 10 carbon atoms substituted with a hydroxyl group, an alkoxy group having 1 to 10 carbon atoms, an amido group having 2 to 11 carbon atoms, an alkylthio group having 1 to 10 carbon atoms, an acyl group having 1 to 10 carbon atoms, an ester group having 2 to 11 carbon atoms, an aryl group having 6 to 20 carbon atoms, an aryl group having 6 to 20 carbon atoms substituted with an electron donating group and/or an electron withdrawing group, a benzyl group substituted with an electron-donating group and/or an electron withdrawing group, a cyano group, a methylthio group and a nitro group.

A case where two or more of R⁶, R⁷, R⁸, R⁹ and R¹⁰ join together to form a condensed ring, such as naphthalene, anthracene, phenanthrene and indene, by sharing the atoms of the benzene ring to which R⁶, R⁷, R⁸, R⁹ and R¹⁰ are attached is preferred, because the absorption wavelength is shifted toward a longer wavelength.

Among the compounds represented by the above formula (4), compounds represented by the following formula (5).

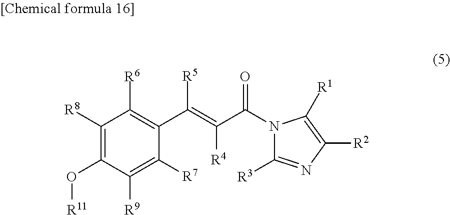

In the formula, R¹, R² and R³ are used synonymously with those in formulas (3) and (4); R⁴ to R⁹ are used synonymously with those in formula (4); R¹¹ represents a hydrogen atom or an organic group; R⁶ and R⁷ shall not be a hydroxyl group; and two or more of R⁶, R⁷, R⁸ and R⁹ may join together to form a cyclic structure which may include a bond of a hetero atom, are preferred.

The compounds represented by formula (5) have excellent solubility in organic solvents because they have a substituent —O—R¹¹.

In formula (5), in a case where R¹¹ is an organic group, those exemplified with regard to R¹, R² and R³ may be referred to as the organic group. This organic group may include a hetero atom. This organic group may be any of linear, branched, or cyclic. For R¹, a hydrogen atom or an alkyl group having 1 to 12 carbon atoms is preferred, and a methyl group is more preferred.

Preferred examples of the compound (A-1) also include the compounds represented by the following formula (6).

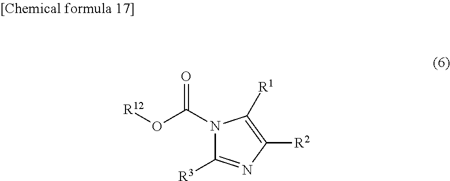

In the formula, R¹, R² and R³ each independently represent a hydrogen atom, a halogen atom, a hydroxyl group, a mercapto group, a sulfide group, a silyl group, a silanol group, a nitro group, a nitroso group, a phosphino group, a sulfonato group, a phosphinyl group, a phosphonato group, or an organic group; and R¹² represents an optionally substituted hydrocarbon group.

R¹, R² and R³ in the formula (6) are the same as those explained with respect to the formula (3).

In the formula (6), examples of R¹² include an alkyl group having 1 to 20 carbon atoms, an alkenyl group having 2 to 20 carbon atoms, an optionally substituted aryl group having 6 to 20 carbon atoms, and an optionally substituted aralkyl group having 7 to 20 carbon atoms, and an optionally substituted aralkyl group having 7 to 20 carbon atoms is preferred. In a case where the aryl group or the aralkyl group is substituted, examples of the substituent include a halogen atom, a nitro group, an alkyl group having 1 to 4 carbon atoms, and an alkoxy group having 1 to 4 carbon atoms.

The compound represented by the formula (6) can be synthesized by the reaction of an imidazole compound represented by the formula (3) and a chloroformate represented by the following formula (7), by the reaction of an imidazole compound represented by the formula (3) and a dicarbonate represented by the following formula (8), or by the reaction of a carbonylimidazole compound represented by the following formula (9) and an alcohol represented by the following formula (10)

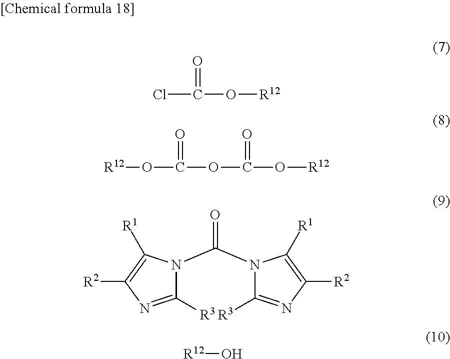

R¹, R² and R³ in the formulas (7) to (10) are as defined in the formula (3), and R¹² is as defined in the formula (6).

Specific examples of the particularly suitable compounds as the compound (A-1) are shown below.

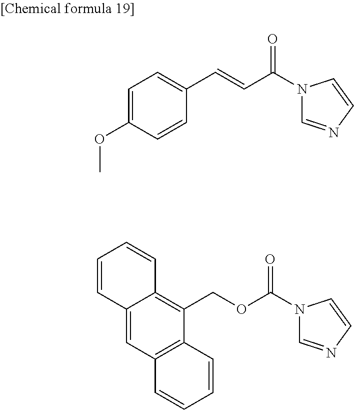 [SMILES: COc1ccc(/C=C/C(=O)n2ccnc2)cc1 ; O=C(OCc1c2ccccc2cc2ccccc12)n1ccnc1]

### [Oxime Ester Compound (A-2)]

The oxime ester compound (A-2) decomposes by the action of at least one of light and heat to generate at least one of a base and an acid. The conversion of the polybenzoxazole precursor into the polybenzoxazole resin in the energy-sensitive resin composition according to the present invention is accelerated by the base or acid generated by the decomposition of compound (A-2).

Preferred examples of the compound (A-2) include the compounds represented by the following formula (D1).

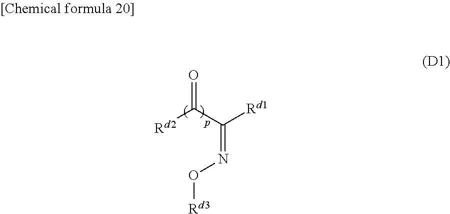

In the formula, R^{d1} is an aliphatic hydrocarbon group having 1 to 10 carbon atoms which may have a substituent, an aryl group which may have a substituent, or a carbazolyl group which may have a substituent, R^{d2} is an aliphatic hydrocarbon group having 1 to 10 carbon atoms or an aryl group which may have a substituent, R^{d3} is a hydrogen atom or a group represented by —CO—R^{d5}, and R^{d5} is a hydrogen atom, an alkyl group having 1 to 6 carbon atoms, or an aryl group which may have a substituent.

In a case where R^{d1} in the formula (D1) is an aryl group which may have a substituent, examples of the aryl group which may have a substituent include a phenyl group which may have a substituent, a naphthyl group which may have a substituent, an anthryl group which may have a substituent, and a phenanthrenyl group which may have a substituent. Among these groups, a phenyl group which may have a substituent or a naphthyl group which may have a substituent is preferable, and a phenyl group which may have a substituent is more preferable.

In a case where an aryl group has a substituent, the number of substituents bonded to the aryl group is not particularly limited. In a case where an aryl group has plural substituents, the plural substituents may be the same as or different from each other. The type of substituent which an aryl group may have is not particularly limited within a range not impairing the object of the present invention. Suitable examples of the substituent include an organic group, an amino group, a halogen atom, a nitro group, and a cyano group.

In a case where the substituent is an organic group, the type of the organic group is not particularly limited within a range not impairing the object of the present invention, and is suitably selected from various organic groups. Suitable examples of the organic group include an alkyl group, an alkoxy group, a cycloalkyl group, a cycloalkoxy group, a saturated aliphatic acyl group, an alkoxycarbonyl group, a saturated aliphatic acyloxy group, a phenyl group which may have a substituent, a phenoxy group which may have a substituent, a benzoyl group which may have a substituent, a phenoxycarbonyl group which may have a substituent, a benzoyloxy group which may have a substituent, a phenylalkyl group which may have a substituent, a naphthyl group which may have a substituent, a naphthoxy group which may have a substituent, a naphthoyl group which may have a substituent, a naphthoxycarbonyl group which may have a substituent, a naphthoyloxy group which may have a substituent, a naphthylalkyl group which may have a substituent, a heterocyclyl group which may have a substituent, an amino group substituted with one or two organic groups, a morpholin-1-yl group, and a piperazin-1-yl group. In the number of carbon atoms of the substituent, the number of carbon atoms of a substituent which the substituent further has is not included.

In a case where the organic group is an alkyl group, the number of carbon atoms thereof is preferably 1 to 20, and more preferably 1 to 6. In addition, in a case where the organic group is an alkyl group, the alkyl group may be linear or branched. Specific examples thereof in a case where the organic group is an alkyl group include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, and an isodecyl group. In addition, in a case where the organic group is an alkyl group, the alkyl group may include an ether bond (—O—) in the carbon chain. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, and a methoxypropyl group.

In a case where the organic group is an alkoxy group, the number of carbon atoms thereof is preferably 1 to 20, and more preferably 1 to 6. In addition, in a case where the organic group is an alkoxy group, the alkoxy group may be linear or branched. Specific examples thereof in a case where the organic group is an alkoxy group include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, and an isodecyloxy group. In addition, in a case where the organic group is an alkoxy group, the alkoxy group may include an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, and a methoxypropyloxy group.

In a case where the organic group is a cycloalkyl group or a cycloalkoxy group, the number of carbon atoms thereof is preferably 3 to 10, and more preferably 3 to 6. Specific examples thereof in a case where the organic group is a cycloalkyl group include a cyclopropyl group, a cyclobutyl group, a cyclopentyl group, a cyclohexyl group, a cycloheptyl group, and a cyclooctyl group. Specific examples thereof in a case where the organic group is a cycloalkoxy group include a cyclopropyloxy group, a cyclobutyloxy group, a cyclopentyloxy group, a cyclohexyloxy group, a cycloheptyloxy group, and a cyclooctyloxy group.

In a case where the organic group is a saturated aliphatic acyl group or a saturated aliphatic acyloxy group, the number of carbon atoms thereof is preferably 2 to 20, and more preferably 2 to 7. Specific examples thereof in a case where the organic group is a saturated aliphatic acyl group include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, and an n-hexadecanoyl group. Specific examples thereof in a case where the organic group is a saturated aliphatic acyloxy group include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, and an n-hexadecanoyloxy group.

In a case where the organic group is an alkoxycarbonyl group, the number of carbon atoms thereof is preferably 2 to 20, and more preferably 2 to 7. Specific examples thereof in a case where the organic group is an alkoxycarbonyl group include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, and an isodecyloxycarbonyl group.

In a case where the organic group is a phenylalkyl group, the number of carbon atoms thereof is preferably 7 to 20, and more preferably 7 to 10. In addition, in a case where the organic group is a naphthylalkyl group, the number of carbon atoms thereof is preferably 11 to 20, and more preferably 11 to 14. Specific examples thereof in a case where the organic group is a phenylalkyl group include a benzyl group, a 2-phenylethyl group, a 3-phenylpropyl group, and a 4-phenylbutyl group. Specific examples thereof in a case where the organic group is a naphthylalkyl group include an α-naphthylmethyl group, a β-naphthylmethyl group, a 2-(α-naphthyl)ethyl group, and a 2-(β-naphthyl)ethyl group. In a case where the organic group is a phenylalkyl group or a naphthylalkyl group, the organic group may further have a substituent on the phenyl group or the naphthyl group.

In a case where the organic group is a heterocyclyl group, the heterocyclyl group is a 5-membered or 6-membered monocyclic ring including one or more N, S, and O, or a heterocyclyl group in which the monocyclic rings are condensed together or the monocyclic ring and a benzene ring are condensed. In a case where the heterocyclyl group is a condensed ring, a condensed ring having 3 or less rings is used. Examples of the heterocyclic ring constituting such heterocyclyl group include furan, thiophene, pyrrole, oxazole, isoxazole, thiazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, and quinoxaline. In a case where the organic group is a heterocyclyl group, the heterocyclyl group may further have a substituent.

In a case where the organic group is an amino group substituted with one or two organic groups, suitable examples of the organic group bonded to the nitrogen atom include an alkyl group having 1 to 20 carbon atoms, a cycloalkyl group having 3 to 10 carbon atoms, a saturated aliphatic acyl group having 2 to 20 carbon atoms, a phenyl group which may have a substituent, a benzoyl group which may have a substituent, a phenylalkyl group having 7 to 20 carbon atoms which may have a substituent, a naphthyl group which may have a substituent, a naphthoyl group which may have a substituent, a naphthylalkyl group having 11 to 20 carbon atoms which may have a substituent, and a heterocyclyl group. In a case where R^{d1} is an aryl group which may have a substituent, specific examples of these suitable organic groups are the same as specific examples of the organic group which the aryl group may have as a substituent. Specific examples of the amino group substituted with one or two organic groups include a methylamino group, a dimethylamino group, an ethylamino group, a diethylamino group, an n-propylamino group, a di-n-propylamino group, an isopropylamino group, an n-butylamino group, an di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoylamino group, an n-hexanoylamino group, an n-heptanoylamino group, an n-octanoylamino group, an n-decanoylamino group, a benzoylamino group, an α-naphthoylamino group, and a β-naphthoylamino group.

In a case where R^{d1} is an aryl group which may have a substituent, and in a case where a phenyl group, a naphthyl group, or a heterocyclyl group included in the organic group bonded to the aryl group as a substituent further has a substituent, examples of the substituent include an alkyl group having 1 to 6 carbon atoms, an alkoxy group having 1 to 6 carbon atoms, a saturated aliphatic acyl group having 2 to 7 carbon atoms, an alkoxycarbonyl group having 2 to 7 carbon atoms, a saturated aliphatic acyloxy group having 2 to 7 carbon atoms, a monoalkylamino group having an alkyl group having 1 to 6 carbon atoms, a dialkylamino group having an alkyl group having 1 to 6 carbon atoms, a morpholin-1-yl group, a piperazin-1-yl group, a halogen atom, a nitro group, and a cyano group.

In a case where R^{d1} is an aryl group which may have a substituent, and in a case where a phenyl group, a naphthyl group, or a heterocyclyl group included in the organic group bonded to the aryl group as a substituent further has a substituent, although the number of substituents is not limited within a range not impairing the object of the present invention, the number is preferably 1 to 4. In a case where R^{d1} is an aryl group which may have a substituent, and in a case where a phenyl group, a naphthyl group, or a heterocyclyl group included in the organic group bonded to the aryl group as a substituent has plural substituents, the plural substituents may be the same as or different from each other.

In a case where R^{d1} is an aryl group which may have a substituent, from the viewpoint of the fact that the substituent is chemically stable, steric hinderance is small, synthesis of the compound represented by formula (D1) is easy, and the solubility of the compound represented by the formula (D1) in a solvent is high, as the substituent which the aryl group has, a group selected from the group consisting of a nitro group, an alkyl group having 1 to 6 carbon atoms, an alkoxy group having 1 to 6 carbon atoms, and a saturated aliphatic acyl group having 2 to 7 carbon atoms is preferable, a nitro group or an alkyl group having 1 to 6 carbon atoms is more preferable, and a nitro group or an methyl group is particularly preferable.

In a case where R^{d1} is an aryl group which may have a substituent, R^{d1} is preferably the following formula (D1-1).

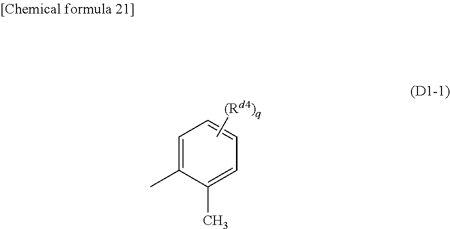

In the formula (D1-1), R^{d4} is a group selected from the group consisting of an organic group, an amino group, a halogen atom, a nitro group, and a cyano group, and q is an integer of 0 to 4.

In a case where R^{d4} is an organic group, and in a case where R^{d1} is an aryl group which may have a substituent, suitable examples of the organic group are the same as examples of the organic group which the aryl group may have as a substituent.

In a case where, for a phenyl group to which R^{d4} is bonded, the position of the bonding between a phenyl group and the main skeleton of an oxime compound is defined as a 1-position and the position of a methyl group is defined as a 2-position, the position where R^{d4} is bonded to the phenyl group is preferably a 4-position or a 5-position, and more preferably a 5-position. In addition, q is preferably an integer of 0 to 3, more preferably an integer of 0 to 2, and particularly preferably 0 or 1.

In the above formula (D1), in a case where R^{d1} is an aliphatic hydrocarbon group which may have a substituent, the number of carbon atoms is 1 to 10. In this number of carbon atoms, the number of carbon atoms of a substituent is not included. The number of carbon atoms of the aliphatic hydrocarbon group is preferably 1 to 9, and more preferably 1 to 8. The aliphatic hydrocarbon group may be a saturated aliphatic hydrocarbon group, or may be a hydrocarbon group having an unsaturated bond. The structure of the aliphatic hydrocarbon group may be a linear structure, a branched structure, a cyclic structure, or a structure obtained by combination of these structures, and is preferably a linear structure.

In a case where R^{d1} is a linear aliphatic hydrocarbon group in the above formula (D1), suitable examples thereof include a methyl group, an ethyl group, an n-propyl group, an n-butyl group, an n-pentyl group, an n-hexyl group, an n-heptyl group, an n-octyl group, an n-nonyl group, and an n-decyl group.

In a case where R^{d1} is a cyclic aliphatic hydrocarbon group, suitable examples thereof include a cyclopentyl group and a cyclohexyl group.

In a case where R^{d1} is a structure obtained by combination of a linear aliphatic hydrocarbon group and a cyclic aliphatic hydrocarbon group, suitable examples thereof include a cyclohexylmethyl group, a cyclopentylmethyl group, a 2-cyclohexylethyl group, a 2-cyclopentylethyl group, a 3-cyclohexyl-n-propyl group, and a 3-cyclopentyl-n-propyl group, and among these groups, a 2-cyclohexylethyl group or a 2-cyclopentylethyl group is preferable.

In a case where R^{d1} is an aliphatic hydrocarbon group, examples of the substituent which the aliphatic hydrocarbon group may have include a hydroxyl group, a halogen atom, a cyano group, an alkoxy group having 1 to 10 carbon atoms, an alkylthio group having 1 to 10 carbon atoms, an aryl group which may have a substituent, an aryloxy group which may have a substituent, an arylthio group which may have a substituent, a saturated aliphatic acyl group having 2 to 10 carbon atoms, an arylcarbonyl group which may have a substituent, an amino group, an amino group substituted with one or two alkyl groups having 1 to 6 carbon atoms, and an amino group substituted with one or two aryl groups which may have a substituent. The number of carbon atoms of these substituents is not included in the number of carbon atoms of an aliphatic hydrocarbon group.

In a case where the substituent which an aliphatic hydrocarbon group has is an amino group substituted with an aryl group which may have a substituent, an aryloxy group which may have a substituent, an arylthio group which may have a substituent, an arylcarbonyl group which may have a substituent, or one or two aryl groups which may have a substituent, examples of the aryl group included in these groups include a phenyl group, a naphthyl group, an anthryl group, and a phenanthryl group, and a phenyl group or a naphthyl group is preferable, and a phenyl group is more preferable.

In a case where the substituent which an aliphatic hydrocarbon group has is an amino group substituted with an aryl group which may have a substituent, an aryloxy group which may have a substituent, an arylthio group which may have a substituent, an arylcarbonyl group which may have a substituent, or one or two aryl groups which may have a substituent, examples of the substituent which the aryl group may have, included in these groups, include a hydroxyl group, a halogen atom, a cyano group, a nitro group, an alkyl group having 1 to 6 carbon atoms, an alkoxy group having 1 to 6 carbon atoms, and a saturated aliphatic acyl group having 2 to 7 carbon atoms.

Specific examples of the substituents described above as a substituent which the aliphatic hydrocarbon group may have in a case where R^{d1} is an aliphatic hydrocarbon group are the same as those of the substituent which the aryl group may have in a case where R^{d1} is an aryl group, within the range of the number of carbon atoms described above.

In a case where R^{d1} is a carbazolyl group which may have a substituent, the type of substituent is not particularly limited within a range not impairing the object of the present invention. Suitable examples of the substituent which a carbazolyl group may have on the carbon atom include an alkyl group having 1 to 20 carbon atoms, an alkoxy group having 1 to 20 carbon atoms, a cycloalkyl group having 3 to 10 carbon atoms, a cycloalkoxy group having 3 to 10 carbon atoms, a saturated aliphatic acyl group having 2 to 20 carbon atoms, an alkoxycarbonyl group having 2 to 20 carbon atoms, a saturated aliphatic acyloxy group having 2 to 20 carbon atoms, a phenyl group which may have a substituent, a phenoxy group which may have a substituent, a phenylthio group which may have a substituent, a phenylcarbonyl group which may have a substituent, a benzoyl group which may have a substituent, a phenoxycarbonyl group which may have a substituent, a benzoyloxy group which may have a substituent, a phenylalkyl group having 7 to 20 carbon atoms which may have a substituent, a naphthyl group which may have a substituent, a naphthoxy group which may have a substituent, a naphthylcarbonyl group which may have a substituent, a naphthoyl group which may have a substituent, a naphthoxycarbonyl group which may have a substituent, a naphthoyloxy group which may have a substituent, a naphthylalkyl group having 11 to 20 carbon atoms which may have a substituent, a heterocyclyl group which may have a substituent, a heterocyclylcarbonyl group which may have a substituent, an amino group, an amino group substituted with one or two organic groups, a morpholin-1-yl group, a piperazin-1-yl group, a halogen atom, a nitro group, and a cyano group.

In a case where R^{d1} is a carbazolyl group which may have a substituent, suitable examples of the substituent which the carbazolyl group may have on the nitrogen atom include an alkyl group having 1 to 20 carbon atoms, a cycloalkyl group having 3 to 10 carbon atoms, a saturated aliphatic acyl group having 2 to 20 carbon atoms, an alkoxycarbonyl group having 2 to 20 carbon atoms, a phenyl group which may have a substituent, a benzoyl group which may have a substituent, a phenoxycarbonyl group which may have a substituent, a phenylalkyl group having 7 to 20 carbon atoms which may have a substituent, a naphthyl group which may have a substituent, a naphthoyl group which may have a substituent, a naphthoxycarbonyl group which may have a substituent, a naphthylalkyl group having 11 to 20 carbon atoms which may have a substituent, a heterocyclyl group which may have a substituent, and a heterocyclylcarbonyl group which may have a substituent. Among these substituents, an alkyl group having 1 to 20 carbon atoms is preferable, an alkyl group having 1 to 6 carbon atoms is more preferable, and an ethyl group is particularly preferable.

Specific examples of the substituent which the carbazolyl group may have are the same as examples of the substituent which an aryl group has in a case where R^{d1} is an aryl group which may have a substituent regarding an alkyl group, an alkoxy group, a cycloalkyl group, a cycloalkoxy group, a saturated aliphatic acyl group, an alkoxycarbonyl group, a saturated aliphatic acyloxy group, a phenylalkyl group which may have a substituent, a naphthylalkyl group which may have a substituent, a heterocyclyl group which may have a substituent, and an amino group substituted with one or two organic groups.

In a case where a phenyl group, a naphthyl group, or a heterocyclyl group included in a substituent which the carbazolyl group for R^{d1} has further has a substituent, examples of the substituent include an alkyl group having 1 to 6 carbon atoms; an alkoxy group having 1 to 6 carbon atoms; a saturated aliphatic acyl group having 2 to 7 carbon atoms; an alkoxycarbonyl group having 2 to 7 carbon atoms; saturated aliphatic acyloxy group having 2 to 7 carbon atoms; a phenyl group; a naphthyl group; a benzoyl group; a naphthoyl group; a benzoyl group substituted with a group selected from the group consisting of an alkyl group having 1 to 6 carbon atoms, a morpholin-1-yl group, a piperazin-1-yl group, and a phenyl group; a monoalkylamino group having an alkyl group having 1 to 6 carbon atoms; a dialkylamino group having an alkyl group having 1 to 6 carbon atoms; a morpholin-1-yl group; a piperazin-1-yl group; a halogen; a nitro group; and a cyano group. In a case where a phenyl group, a naphthyl group, or a heterocyclyl group included in a substituent which the carbazolyl group has further has a substituent, although the number of substituents thereof is not limited within a range not impairing the object of the present invention, the number is preferably 1 to 4. In a case where a phenyl group, a naphthyl group, or a heterocyclyl group has plural substituents, the plural substituents may be the same as or different from each other.

R^{d2} is an aliphatic hydrocarbon group having 1 to 10 carbon atoms or an aryl group which may have a substituent.

In a case where R^{d2} is an aliphatic hydrocarbon group, the number of carbon atoms of the aliphatic hydrocarbon group is preferably 1 to 6, and more preferably 1. The aliphatic hydrocarbon group may be a saturated aliphatic hydrocarbon group, or may be a hydrocarbon group having an unsaturated bond. The structure of the aliphatic hydrocarbon group may be a linear structure, a branched structure, a cyclic structure, or a structure obtained by combination of these structures, and is preferably a linear structure.

In a case where R^{d2} is a linear aliphatic hydrocarbon group, suitable examples thereof include a methyl group, an ethyl group, an n-propyl group, an n-butyl group, an n-pentyl group, an n-hexyl group, an n-heptyl group, an n-octyl group, an n-nonyl group, and an n-decyl group. Among these, a methyl group is particularly preferable.

In a case where R^{d2} is an aryl group which may have a substituent, examples thereof include a phenyl group which may have a substituent, a naphthyl group which may have a substituent, an anthryl group which may have a substituent, and a phenanthrenyl group which may have a substituent. Among these groups, a phenyl group which may have a substituent or a naphthyl group which may have a substituent is preferable, and a phenyl group which may have a substituent is more preferable.

With respect to R^{d2}, the substituent which an aryl group has is not particularly limited within a range not impairing the object of the present invention. Examples of the suitable substituent which an aryl group may have on the carbon atom include an alkyl group having 1 to 20 carbon atoms, an alkoxy group having 1 to 20 carbon atoms, a cycloalkyl group having 3 to 10 carbon atoms, a cycloalkoxy group having 3 to 10 carbon atoms, a saturated aliphatic acyl group having 2 to 20 carbon atoms, an alkoxycarbonyl group having 2 to 20 carbon atoms, a saturated aliphatic acyloxy group having 2 to 20 carbon atoms, a phenyl group which may have a substituent, a phenoxy group which may have a substituent, a phenylthio group which may have a substituent, a benzoyl group which may have a substituent, a phenoxycarbonyl group which may have a substituent, a benzoyloxy group which may have a substituent, a phenylalkyl group having 7 to 20 carbon atoms which may have a substituent, a naphthyl group which may have a substituent, a naphthoxy group which may have a substituent, a naphthoyl group which may have a substituent, a naphthoxycarbonyl group which may have a substituent, a naphthoyloxy group which may have a substituent, a naphthylalkyl group having 11 to 20 carbon atoms which may have a substituent, a heterocyclyl group which may have a substituent, a heterocyclylcarbonyl group which may have a substituent, an amino group, an amino group substituted with one or two organic groups, a morpholin-1-yl group, a piperazin-1-yl group, a halogen atom, a nitro group, and a cyano group.

Specific examples of the substituent which the aryl group may have are the same as examples of the substituent which an aryl group may have in a case where R^{d1} is an aryl group which may have a substituent regarding an alkyl group, an alkoxy group, a cycloalkyl group, a cycloalkoxy group, a saturated aliphatic acyl group, an alkoxycarbonyl group, a saturated aliphatic acyloxy group, a phenylalkyl group which may have a substituent, a naphthylalkyl group which may have a substituent, a heterocyclyl group which may have a substituent, and an amino group substituted with one or two organic groups.

In a case where a phenyl group, a naphthyl group, or a heterocyclyl group included in a substituent which the aryl group for R^{d2} has further has a substituent, examples of the substituent include an alkyl group having 1 to 6 carbon atoms; an alkoxy group having 1 to 6 carbon atoms; a saturated aliphatic acyl group having 2 to 7 carbon atoms; an alkoxycarbonyl group having 2 to 7 carbon atoms; saturated aliphatic acyloxy group having 2 to 7 carbon atoms; a phenyl group; a naphthyl group; a benzoyl group; a naphthoyl group; a benzoyl group substituted with a group selected from the group consisting of an alkyl group having 1 to 6 carbon atoms, a morpholin-1-yl group, a piperazin-1-yl group, and a phenyl group; a monoalkylamino group having an alkyl group having 1 to 6 carbon atoms; a dialkylamino group having an alkyl group having 1 to 6 carbon atoms; a morpholin-1-yl group; a piperazin-1-yl group; a halogen atom; a nitro group; and a cyano group. In a case where a phenyl group, a naphthyl group, or a heterocyclyl group included in a substituent which the aryl group has further has a substituent, although the number of substituents thereof is not limited within a range not impairing the object of the present invention, the number is preferably 1 to 4. In a case where a phenyl group, a naphthyl group, or a heterocyclyl group has plural substituents, the plural substituents may be the same as or different from each other.

R^{d3} in the formula (D1) is a hydrogen atom or a group represented by —CO—R^{d5}. In the group represented by —CO—R^{d5}, R^{d5} is a hydrogen atom, an alkyl group having 1 to 6 carbon atoms, or an aryl group which may have a substituent. In a case where R^{d5} is an aryl group which may have a substituent, the substituent which the aryl group may have is the same as the substituent which the aryl group may have in a case where R^{d1} is an aryl group which may have a substituent. In a case where R^{d5} is an aryl group which may have a substituent, the aryl group may have two or more substituents. In this case, the substituents which the aryl group has may be the same as or different from each other. R^{d5} is preferably a hydrogen atom, an acetyl group, a propionyl group, or a benzoyl group, and more preferably a hydrogen atom, an acetyl group, or a benzoyl group.

As the compound represented by the formula (D1), a compound in which, in formula (D1), R^{d1} is an aliphatic hydrocarbon group having 1 to 10 carbon atoms which may have a substituent or an aryl group which may have a substituent, and R^{d2} is a group represented by the following formula (D1-2), or a compound in which, in the formula (D1), which R^{d1} is a group represented by the following formula (D1-3) is preferable, from the viewpoint of base generation efficiency or acid generation efficiency of the compound, and a compound in which, in the formula (D1), R^{d1} is an aliphatic hydrocarbon group having 1 to 10 carbon atoms which may have a substituent or an aryl group which may have a substituent, and R^{d2} is a group represented by the following formula (D1-2) is more preferable from the viewpoint of obtaining a polybenzoxazole resin having high transparency in which coloring is suppressed.

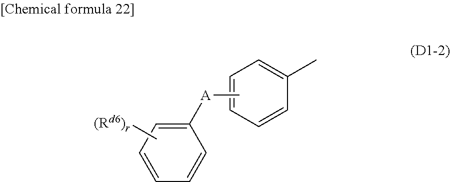

In the formula (D1-2), R^{d6} is a group selected from the group consisting of a monovalent organic group, an amino group, a halogen atom, a nitro group, and a cyano group, A is S or O, and r is an integer of 0 to 4.

In a case where R^{d6} in formula (D1-2) is an organic group, various organic groups can be selected within a range not impairing the object of the present invention. Suitable examples thereof in a case where R^{d6} in the formula (D1-2) is an organic group include an alkyl group having 1 to 6 carbon atoms; an alkoxy group having 1 to 6 carbon atoms; a saturated aliphatic acyl group having 2 to 7 carbon atoms; an alkoxycarbonyl group having 2 to 7 carbon atoms; saturated aliphatic acyloxy group having 2 to 7 carbon atoms; a phenyl group; a naphthyl group; a benzoyl group; a naphthoyl group; a benzoyl group substituted with a group selected from the group consisting of an alkyl group having 1 to 6 carbon atoms, a morpholin-1-yl group, a piperazin-1-yl group, and a phenyl group; a monoalkylamino group having an alkyl group having 1 to 6 carbon atoms; a dialkylamino group having an alkyl group having 1 to 6 carbon atoms; a morpholin-1-yl group; a piperazin-1-yl group; a halogen atom; a nitro group; and a cyano group.

Among the groups represented by R^{d6}, a benzoyl group; a naphthoyl group; a benzoyl group substituted with a group selected from the group consisting of an alkyl group having 1 to 6 carbon atoms, a morpholin-1-yl group, a piperazin-1-yl group, and a phenyl group; or a nitro group is preferable, and a benzoyl group; a naphthoyl group; a 2-methylphenylcarbonyl group; a 4-(piperazin-1-yl)phenylcarbonyl group; or a 4-(phenyl)phenylcarbonyl group is more preferable.

In addition, in the formula (D1-2), r is preferably an integer of 0 to 3, more preferably an integer of 0 or 2, and particularly preferably is 0 or 1. In a case where r is 1, the position where R^{d6} is bonded is preferably the para position with respect to the bonding through which a phenyl group, to which R^{d6} is bonded, is bonded to an oxygen atom or a sulfur atom.

In the formula (D1-2), A is preferably S.

Examples of the substituent in a case where a phenyl group, a naphthyl group, or a heterocyclyl group included in R^{d6} further has a substituent include an alkyl group having 1 to 6 carbon atoms, an alkoxy group having 1 to 6 carbon atoms, a saturated aliphatic acyl group having 2 to 7 carbon atoms, an alkoxycarbonyl group having 2 to 7 carbon atoms, a saturated aliphatic acyloxy group having 2 to 7 carbon atoms, a monoalkylamino group having an alkyl group having 1 to 6 carbon atoms, a dialkylamino group having an alkyl group having 1 to 6 carbon atoms, a morpholin-1-yl group, a piperazin-1-yl group, a halogen atom, a nitro group, and a cyano group. In a case where a phenyl group, a naphthyl group, or a heterocyclyl group included in R^{d6} further has a substituent, although the number of substituents thereof is not limited within a range not impairing the object of the present invention, the number is preferably 1 to 4. In a case where a phenyl group, a naphthyl group, or a heterocyclyl group included in R^{d6} has plural substituents, the plural substituents may be the same as or different from each other.

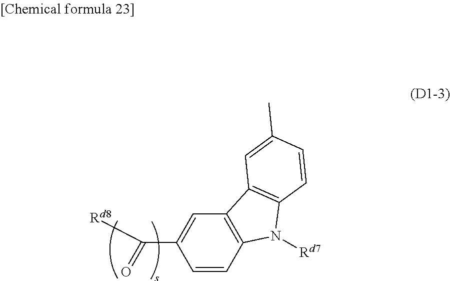

In the formula (D1-3), each of R^{d7} and R^{d8} is a monovalent organic group, and s is 0 or 1.

R^{d7} in formula (12) can be selected from various organic groups within a range not impairing the object of the present invention. Suitable examples of R^{d7} include an alkyl group having 1 to 20 carbon atoms, a cycloalkyl group having 3 to 10 carbon atoms, a saturated aliphatic acyl group having 2 to 20 carbon atoms, an alkoxycarbonyl group having 2 to 20 carbon atoms, a phenyl group which may have a substituent, a benzoyl group which may have a substituent, a phenoxycarbonyl group which may have a substituent, a phenylalkyl group having 7 to 20 carbon atoms which may have a substituent, a naphthyl group which may have a substituent, a naphthoyl group which may have a substituent, a naphthoxycarbonyl group which may have a substituent, a naphthylalkyl group having 11 to 20 carbon atoms which may have a substituent, a heterocyclyl group which may have a substituent, and a heterocyclylcarbonyl group which may have a substituent.

Among the groups represented by R^{d}, an alkyl group having 1 to 20 carbon atoms is preferable, an alkyl group having 1 to 6 carbon atoms is more preferable, and an ethyl group is particularly preferable.

R^{d8} in formula (12) is not particularly limited within a range not impairing the object of the present invention, and can be selected from various organic groups. Specific examples of the suitable group represented by R^{d8} include an alkyl group having 1 to 20 carbon atoms, a phenyl group which may have a substituent, a naphthyl group which may have a substituent, and a heterocyclyl group which may have a substituent. Among these groups, as R^{d8}, a phenyl group which may have a substituent or a naphthyl group which may have a substituent is more preferable, and a 2-methylphenyl group and a naphthyl group are particularly preferable.

Examples of the substituent in a case where a phenyl group, a naphthyl group, or a heterocyclyl group included in R^{d7} or R^{d8} further has a substituent include an alkyl group having 1 to 6 carbon atoms, an alkoxy group having 1 to 6 carbon atoms, a saturated aliphatic acyl group having 2 to 7 carbon atoms, an alkoxycarbonyl group having 2 to 7 carbon atoms, a saturated aliphatic acyloxy group having 2 to 7 carbon atoms, a monoalkylamino group having an alkyl group having 1 to 6 carbon atoms, a dialkylamino group having an alkyl group having 1 to 6 carbon atoms, a morpholin-1-yl group, a piperazin-1-yl group, a halogen, a nitro group, and a cyano group. In a case where a phenyl group, a naphthyl group, or a heterocyclyl group included in R^{d7} or R^{d8} further has a substituent, although the number of substituents thereof is not limited within a range not impairing the object of the present invention, the number is preferably 1 to 4. In a case where a phenyl group, a naphthyl group, or a heterocyclyl group included in R^{d7} or R^{d8} has plural substituents, the plural substituents may be the same as or different from each other.

In a case where p is 0, R^{d2} is an aryl group which may have a substituent, and R^{d3} is a hydrogen atom, the compound represented by the formula (D1) can be synthesized, for example, according to the following scheme 1. Specifically, by acylating an aromatic compound represented by the following formula (1-1) by a Friedel Crafts reaction using a halocarbonyl compound represented by the following formula (1-2), a ketone compound represented by the following formula (1-3) is obtained, and by oximizing the obtained ketone compound (1-3) with hydroxylamine, an oxime compound represented by the following formula (1-4) is obtained. In the following formula (1-2), Hal is a halogen atom, and in the following formulae (1-1), (1-2), (1-3), and (1-4), R^{d1} and R^{d2} are the same as those in the formula (D1).

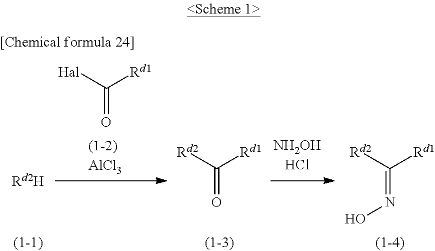

In a case where p is 0, R^{d2} is an aryl group which may have a substituent, and R^{d3} is a group represented by —CO—R^{d5}, the compound represented by the formula (D1) can be synthesized according to the following scheme 2. Specifically, by reacting the oxime compound represented by the formula (1-4) obtained by the method described in the above scheme 1 with an acid anhydride ((R^{d5}CO)₂O) represented by the following formula (1-5) or an acid halide (R^{d5}COHal, Hal is a halogen atom) represented by the following formula (1-6), an oxime ester compound represented by the following formula (1-7) can be obtained. In the following formulae (1-4), (1-5), (1-6), and (1-7), R^{d1}, R^{d2}, and R^{d5} are the same as those in the formula (1).

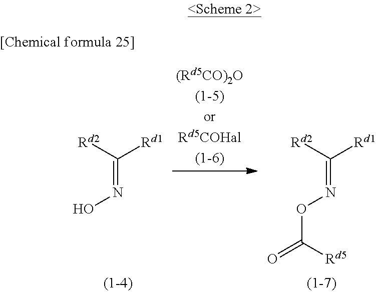

In a case where p is 0, R^{d2} is an aliphatic hydrocarbon group having 1 to 10 carbon atoms, and R^{d3} is a hydrogen atom, by oximizing a ketone compound represented by R^{d2}—CO—R^{d1} with hydroxylamine according to the method described in the scheme 1, the compound represented by the formula (D1) can be obtained as a compound represented by R^{d2}—C(═N—OH)—R^{d}.

In addition, in a case where p is 0, R^{d2} is an aliphatic hydrocarbon group having 1 to 10 carbon atoms, and R^{d3} is a group represented by —CO—R^{d5}, by acylating an oxime compound represented by R^{d2}—C(═N—OH)—R^{d1} according to the method described in the scheme 2, the compound represented by the formula (D1) can be obtained as a compound represented by R^{d2}—C(═N—O—CO—R^{d5})—R_{d1}.

In a case where p is 1 and R^{d3} is a hydrogen atom, the compound represented by the formula (D1) can be synthesized, for example, according to the following scheme 3. Specifically, by reacting a ketone compound represented by the following formula (2-1) with a nitrite ester (RONO, R is an alkyl group having 1 to 6 carbon atoms) represented by the following formula (2-2) in the presence of hydrochloric acid, a ketoxime compound represented by the following formula (2-3) is obtained, and then, a ketoxime compound represented by the following formula (2-3) is obtained. In the following formulae (2-1) and (2-3), R^{d1} and R^{d2} are the same as those in the formula (D1).

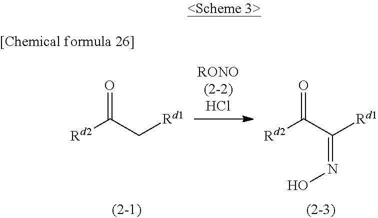

In a case where p is 1 and R^{d3} is a group represented by —CO—R^{d5}, the compound represented by the formula (D1) can be synthesized according to the following scheme 4. Specifically, by reacting the oxime compound represented by the formula (2-3) obtained by the method described in the above scheme 3 with an acid anhydride ((R^{d5}CO)₂O) represented by the following formula (2-4) or an acid halide (R^{d5}COHal, Hal is a halogen atom) represented by the following formula (2-5), an oxime ester compound represented by the following formula (2-6) can be obtained. In the following formulae (2-3), (2-4), (2-5), and (2-6), R^{d1}, R^{d2}, and R^{d5} are the same as those in the formula (D1).

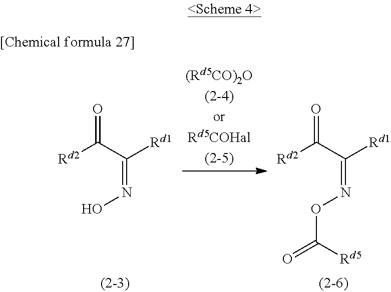

Examples of the particularly suitable compound among the oxime compounds represented by the formula (D1) include compounds represented by the following formulae.

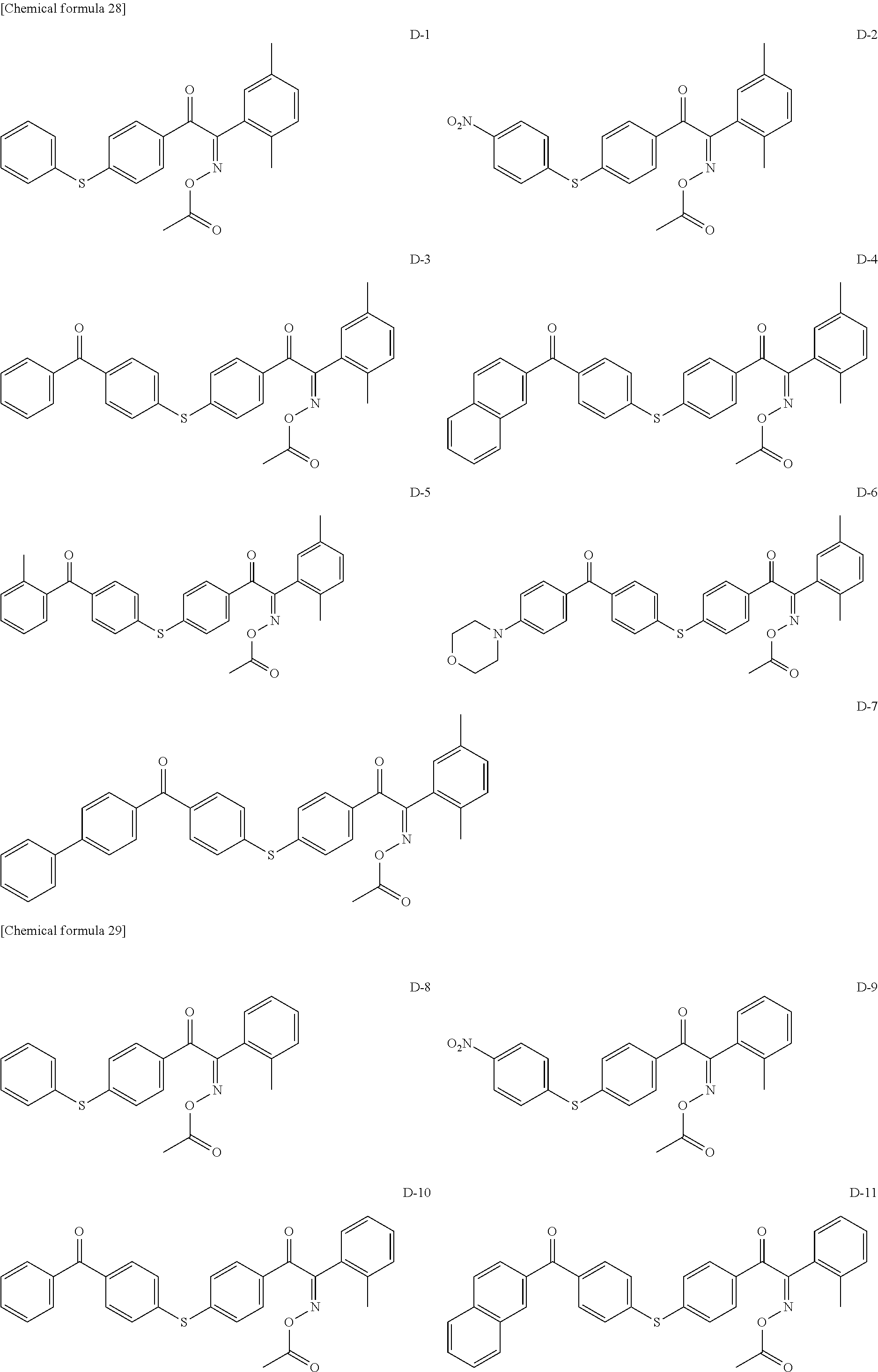

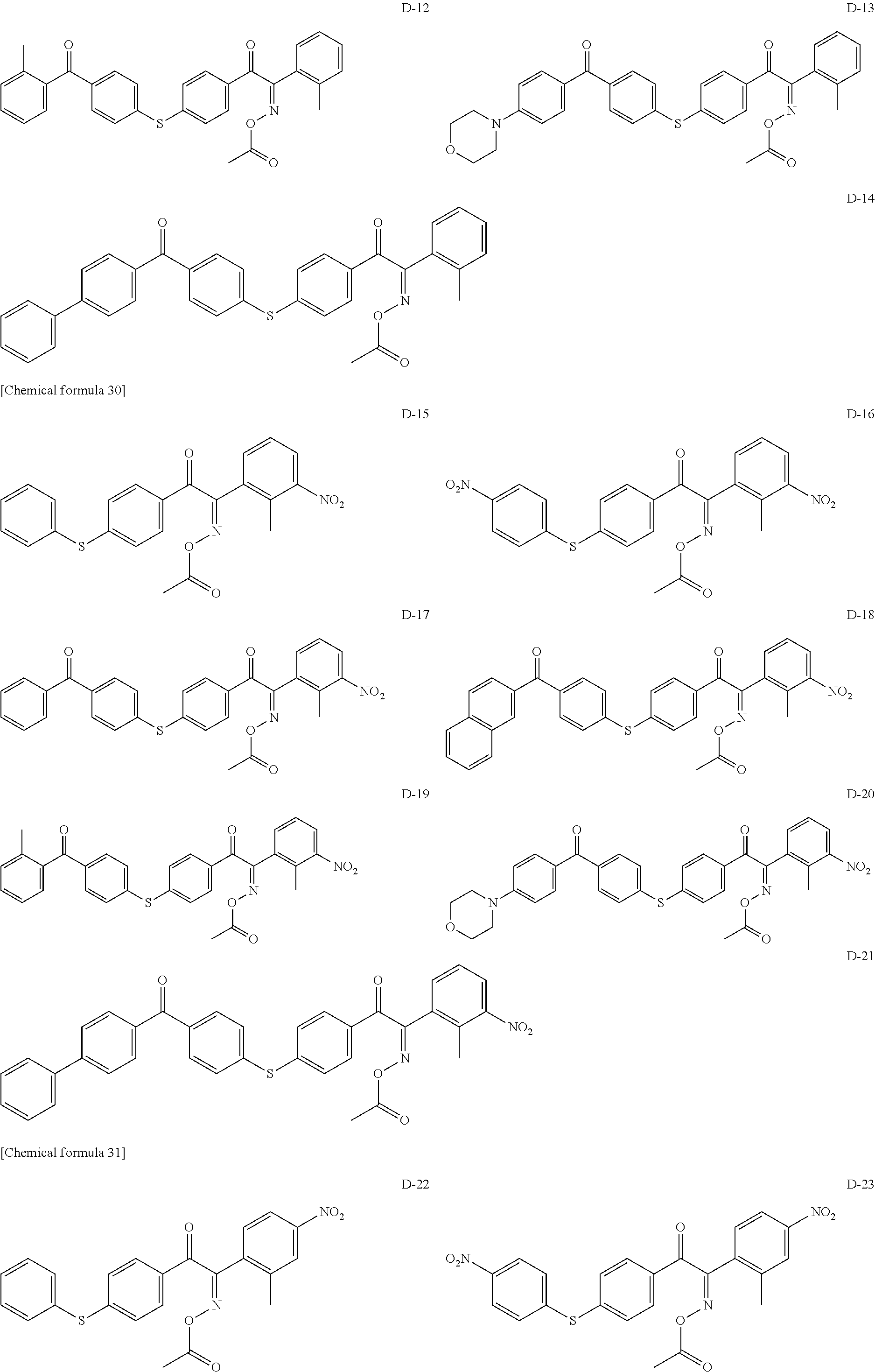

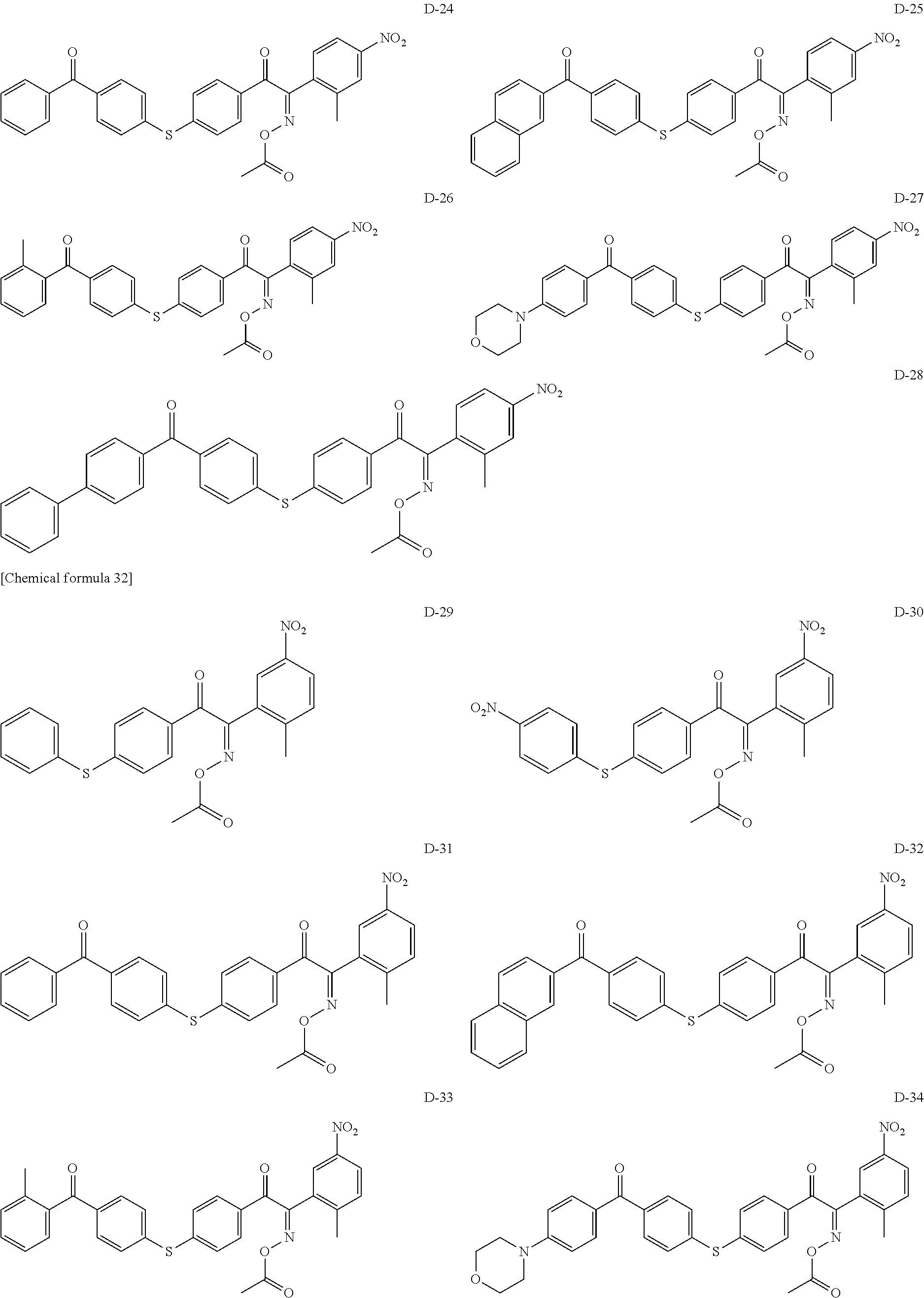

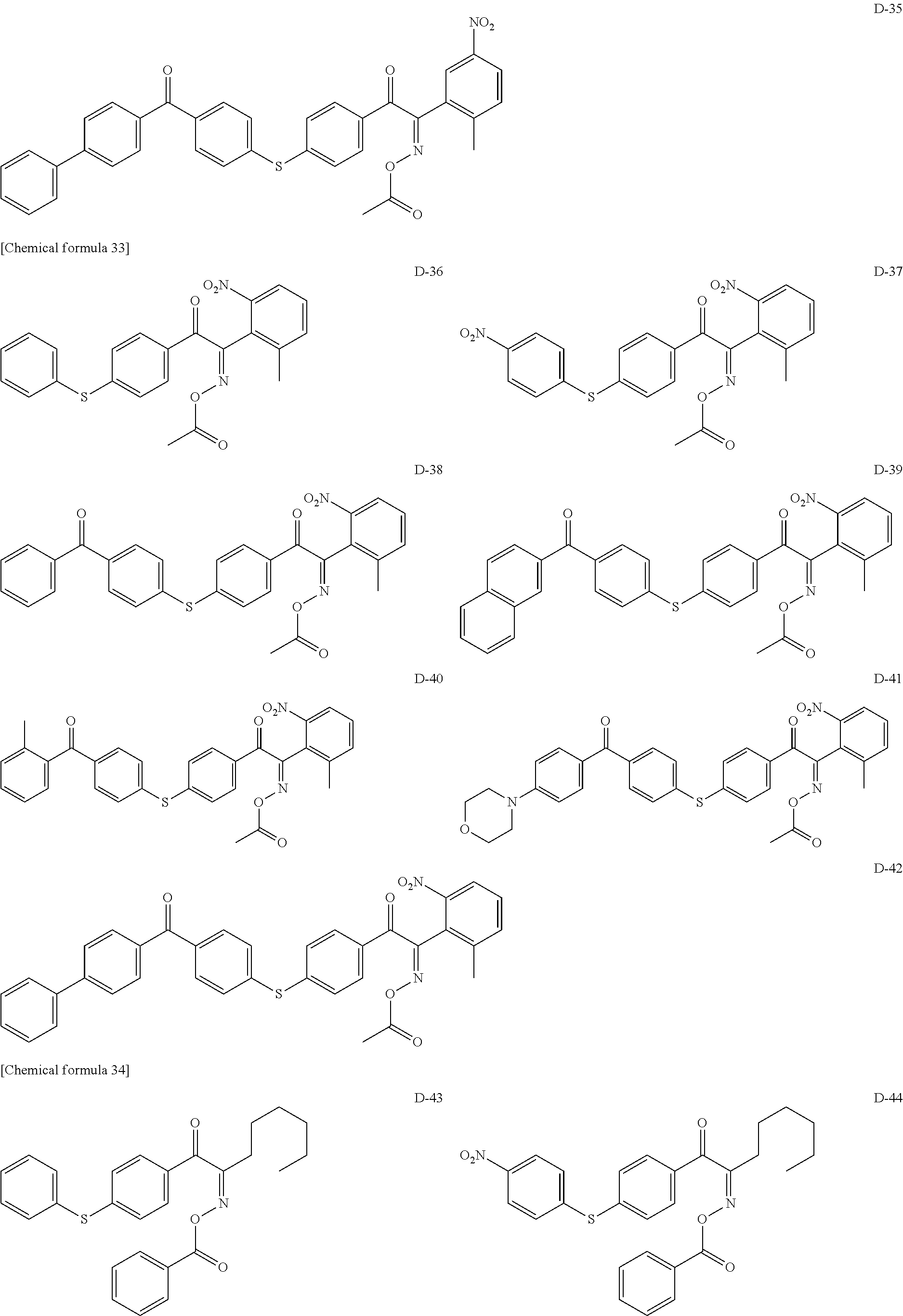

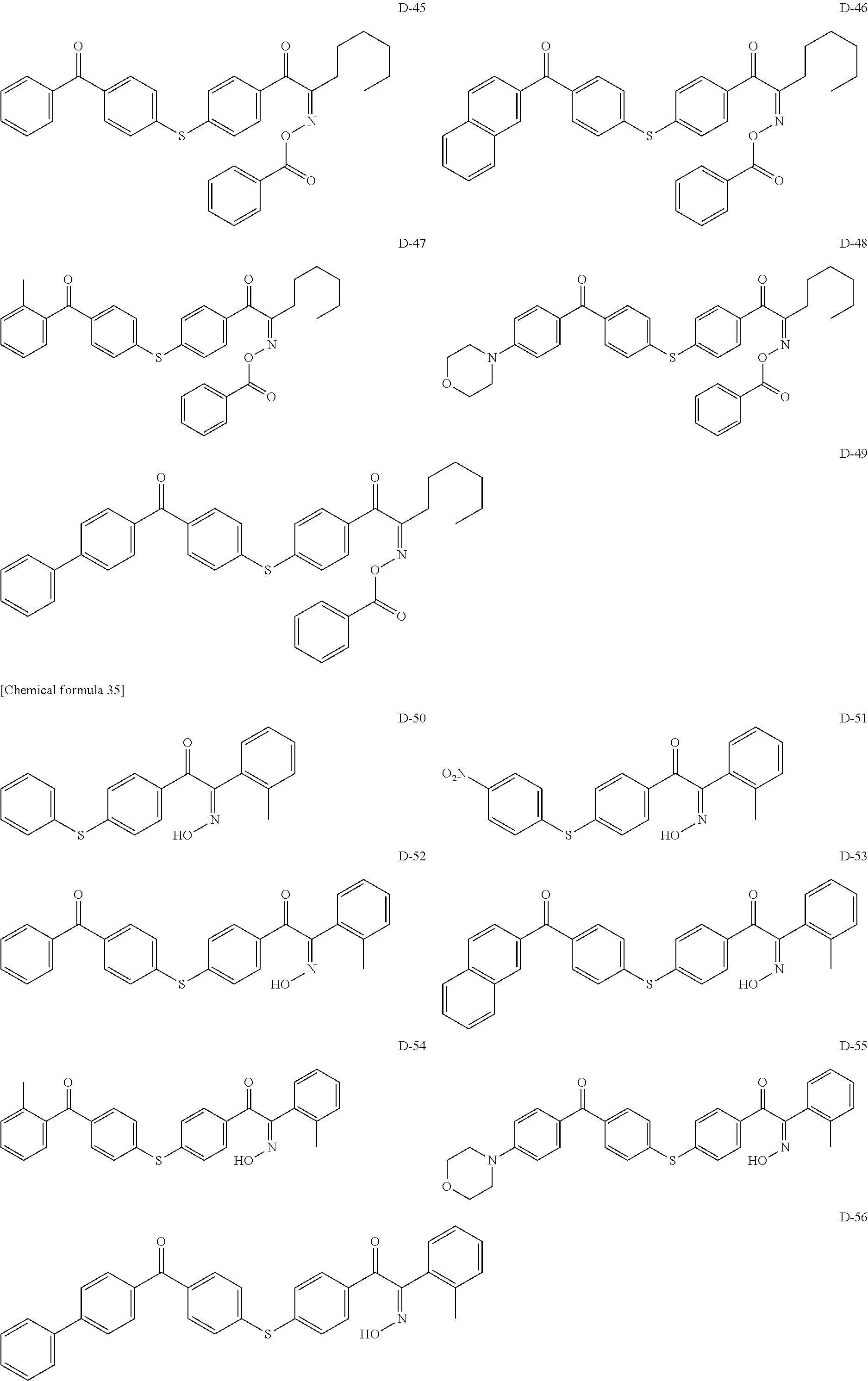

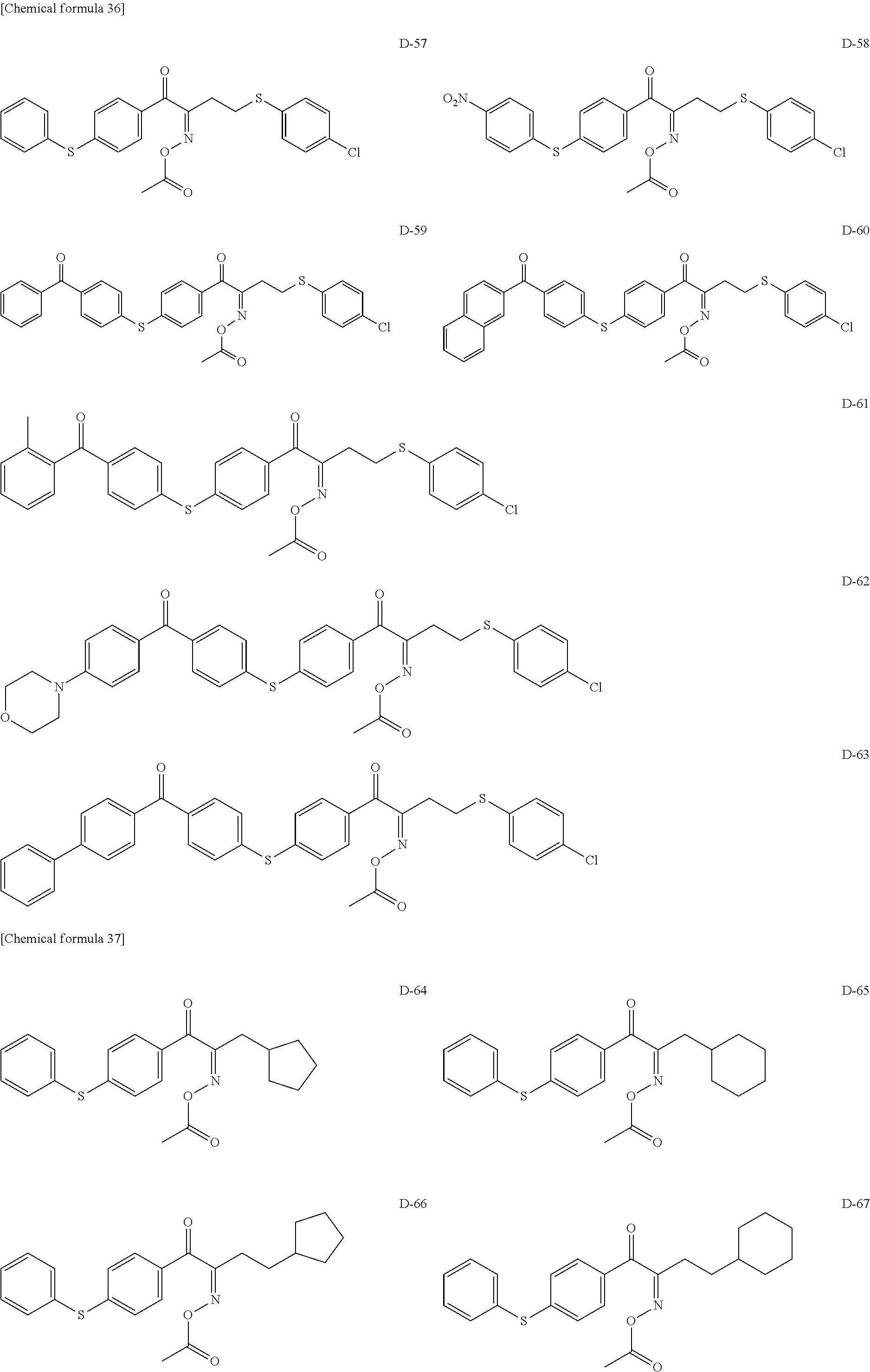

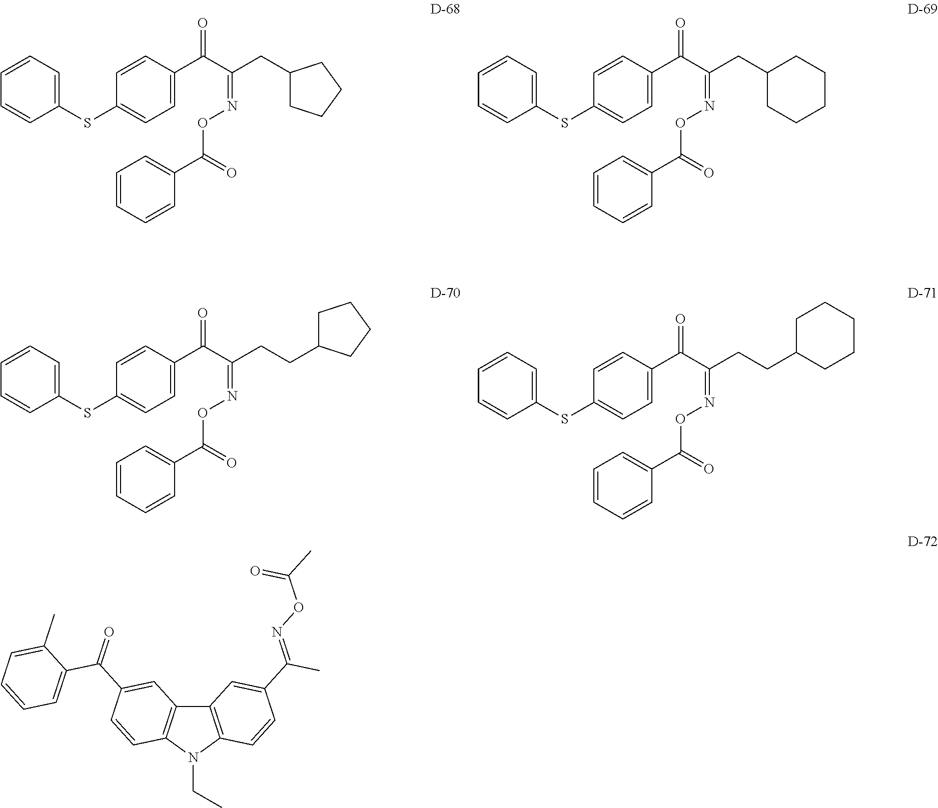 [SMILES: O=C(O/N=C(/CC1CCCC1)C(=O)c1ccc(Sc2ccccc2)cc1)c1ccccc1 ; O=C(O/N=C(/CC1CCCCC1)C(=O)c1ccc(Sc2ccccc2)cc1)c1ccccc1 ; O=C(O/N=C(/CCC1CCCC1)C(=O)c1ccc(Sc2ccccc2)cc1)c1ccccc1 ; O=C(O/N=C(/CCC1CCCCC1)C(=O)c1ccc(Sc2ccccc2)cc1)c1ccccc1 ; CCn1c2ccc(C(=O)c3ccccc3C)cc2c2cc(/C(C)=N/OC(C)=O)ccc21]

The content of the compound (A) in the energy-sensitive resin composition is not particularly limited within a range not impairing the object of the present invention. The content of the compound (A) in the energy-sensitive resin composition is preferably 1 to 50 parts by mass, and more preferably 1 to 30 parts by mass relative to 100 parts by mass of the polybenzoxazole precursor.

### Other Components

The energy-sensitive resin composition according to the present invention may comprise components other than the aforementioned components as far as it does not inhibit the object of the present invention. Examples of the other components include surfactants, plasticizers, viscosity modifiers, anti-foaming agents, and colorants.

### Method of Manufacturing a Polybenzoxazole Film or a Polybenzoxazole Molded Product

The method of manufacturing a polybenzoxazole film or a polybenzoxazole molded product according to the present invention includes: a forming step of forming a coating film or a molded product comprising the energy-sensitive composition according to the present invention; and a decomposing step of decomposing the compound (A) in the coating film or the molded product by exposing or heating the coating film or the molded product.

In the following, each of the steps will be explained.

### Forming Step

In the forming step, the energy-sensitive resin composition according to the present invention is applied onto the surface of an object to be coated or molded in an appropriate molding method to form a coating film or a molded product. Examples of the application method include a dipping method, a spraying method, a bar coating method, a roll coating method, a spin coating method, and a curtain coating method. The thickness of the coating film is not particularly limited. Typically, the thickness of the coating film is preferably 2 to 100 m, and more preferably 3 to 50 m. The thickness of the coating film can be appropriately controlled by means of the application method or by adjusting the solid content or the viscosity of the energy-sensitive resin composition.

After forming the coating film or molded product, the coating film or the molded product may be heated in order to remove the solvent included in the coating film or the molded product. The heating temperature or the heating time is not particularly limited, as far as no heat deterioration or thermal decomposition is caused in the components contained in the energy-sensitive resin composition. In a case where the boiling point of a solvent in the coating film or the molded product is high, the coating film or the molded product may be heated under reduced pressure.

### Decomposing Step

In the decomposing step, the coating film or the molded product formed in the forming step is exposed or heated so that the compound (A) in the coating film or the molded product decomposes. The base or acid which generates by the decomposition of the compound (A) accelerates the conversion of the polybenzoxazole precursor in the coating film or the molded product into the polybenzoxazole resin. Further, in a case where the coating film or the molded product is heated, the conversion into the polybenzoxazole resin also proceeds by the heating. As a result of the conversion into the polybenzoxazole resin, a polybenzoxazole film or a polybenzoxazole molded product is formed.

Examples of radiation to be used for exposing the coating film or the molded product include, for example, ultraviolet rays, electron beams, laser beams and the like, which are emitted from a low-pressure mercury lamp, a high-pressure mercury lamp, a metal halide lamp, a g-line stepper, an i-line stepper and the like. The amount of exposure may vary depending on the light source to be used, the thickness of a coating film or the like, but is usually 1 to 1,000 mJ/cm², and preferably 10 to 500 mJ/cm².

The heating temperature for heating the coating film or the molded product is properly controlled depending upon the decomposition temperature of the compound (A) which is used. For instance, the temperature is set to 120° C. to 350° C., and preferably 150° C. to 350° C. By heating the polybenzoxazole precursor at a temperature falling within such a range, it is possible to form a polybenzoxazole resin while suppressing the heat deterioration or thermal decomposition of the resulting polybenzoxazole resin.

Further, when the polybenzoxazole precursor is heated at a high temperature, a large amount of energy may be consumed or aging deterioration of treatment equipment may be accelerated at a high temperature. Therefore, it is also preferred to heat the polybenzoxazole precursor at relatively low temperatures. Specifically, the upper limit of the temperature at which the polybenzoxazole precursor is heated is preferably 220° C. or lower, more preferably 200° C. or lower, and particularly preferably 190° C. or lower.

### Method of Forming a Pattern

In a case where the compound (A) is a compound which decomposes by the action of light at least to generate at least one of a base and an acid, the method of forming a pattern according to the present invention comprises a forming step of forming a coating film or a molded product comprising the energy-sensitive resin composition according to the present invention; an exposure step of selectively exposing the coating film or the molded product, a development step of developing the coating film or the molded product after the exposing, and a heating step of heating the coating film or the molded product after the developing.

### Forming Step

The forming step in the method of forming patterns is the same as that explained regarding the forming step in the manufacturing step of the polybenzoxazole film or the polybenzoxazole molded product, except that the compound (A) in the energy-sensitive composition according to the present invention is a compound which decomposes at least by the action of light to generate at least one of a base and an acid.

### Exposure Step

In the exposure step, the coating film or the molded product obtained in the forming step is exposed selectively to a predetermined pattern. Selective exposure is generally performed using a mask of a predetermined pattern. The radiation to be used in the exposure or an amount of exposure is the same as that explained regarding the case where the polybenzoxazole film or the molded product is exposed in the decomposing step in the method of manufacturing the polybenzoxazole film or the polybenzoxazole molded product.

### Development Step

In the development step, the unexposed portions are removed from the coating film or the molded product, which has been exposed selectively to a predetermined pattern in the exposure step, thereby developing the coating film or the molded product. The unexposed portions are usually removed by dissolving in an alkaline developing solution. Examples of the developing method include a shower developing method, a spray developing method, a dipping developing method, and a paddle developing method. As an alkaline developing solution, an aqueous solution containing one or more alkali compounds selected from an inorganic alkali compound and an organic alkali compound can be used. The concentration of an alkali compound in a developing solution is not particularly limited, as long as the developing solution can satisfactorily develop the coating film or the molded product after the exposing. Typically, the concentration of an alkali compound in a developing solution is preferably 1 to 10% by mass.

Examples of the inorganic alkali compound include lithium hydroxide, sodium hydroxide, potassium hydroxide, diammonium hydrogen phosphate, dipotassium hydrogen phosphate, disodium hydrogen phosphate, lithium silicate, sodium silicate, potassium silicate, lithium carbonate, sodium carbonate, potassium carbonate, lithium borate, sodium borate, potassium borate, ammonia and the like. Examples of the organic alkali compound include tetramethylammonium hydroxide, tetraethylammonium hydroxide, trimethylhydroxyethylammonium hydroxide, methylamine, dimethylamine, trimethylamine, monoethylamine, diethylamine, triethylamine, n-propylamine, di-n-propylamine, isopropylamine, diisopropylamine, methyldiethylamine, dimethylethanolamine, ethanolamine, triethanolamine and the like.

Further, in the developing solution, a water-soluble organic solvent such as methanol, ethanol, propanol or ethylene glycol, a surfactant, a preservation stabilizer, a resin-dissolution suppressing agent and the like each can be added in an appropriate amount, as needed.

### Heating Step

In the heating step, a coating film or a molded product in which unexposed portions have been removed in the development step, so that predetermined patterns have been developed, is heated. Thereby, conversion of the polybenzoxazole precursor, which has remained in the coating film or the molded product even after the exposure step, into the polybenzoxazole resin is further promoted, so that imidation becomes more sufficient. The heating temperature is similar to the temperature explained for the case where the coating film or the molded product is heated in the decomposing step in the method of manufacturing the polybenzoxazole film or the polybenzoxazole molded product.

### EXAMPLES

In the following, the present invention will be described more specifically by way of Examples, but the present invention is not limited to these Examples.

### Examples 1 to 24 and Comparative Examples 1 to 5

In the examples and the comparative examples, an aromatic diaminediol, a dicarbonyl compound, a solvent, compounds E1 to E5, and a comparative compound C1 described below were used.

Aromatic Diaminediol

DA1: 2,2′-bis(3-amino-4-hydroxyphenyl)hexafluoro propane

DA2: 4,4′-diamino-3,3′-dihydroxybiphenyl

Dicarbonyl compound

DC1: isophthalaldehyde

DC2: terephthalic acid dichloride

Solvent

NMP: N-methyl-2-pyrrolidone

TMU: N,N,N′,N′-tetramethylurea

DMIB: N,N,2-trimethylpropionamide

### Compounds E1 to E5 and Comparative Compound C1

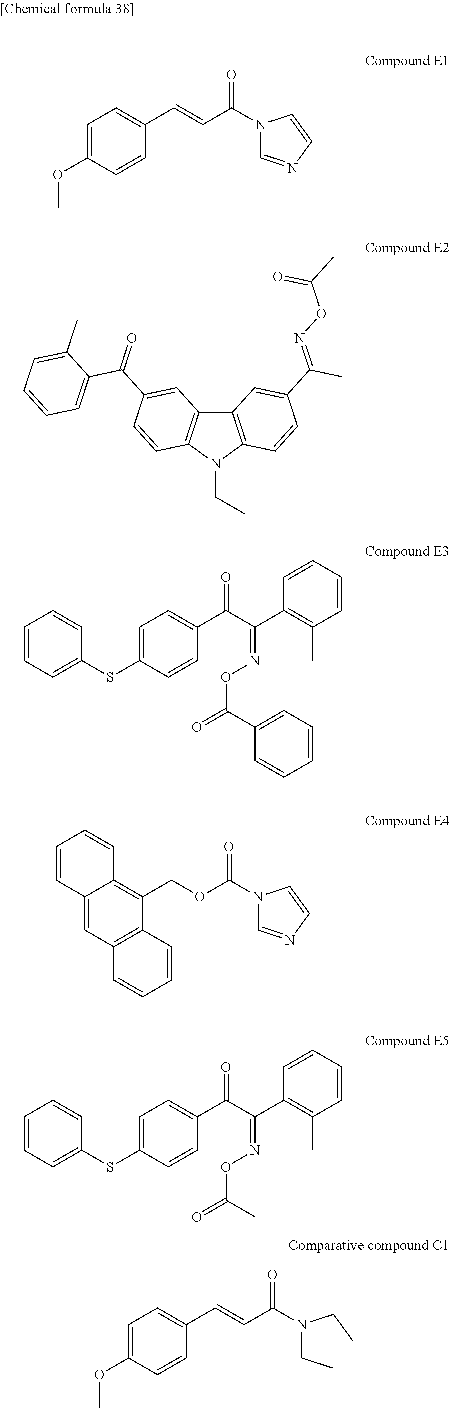 [SMILES: COc1ccc(/C=C/C(=O)n2ccnc2)cc1 ; CCn1c2ccc(C(=O)c3ccccc3C)cc2c2cc(/C(C)=N/OC(C)=O)ccc21 ; Cc1ccccc1/C(=N/OC(=O)c1ccccc1)C(=O)c1ccc(Sc2ccccc2)cc1 ; O=C(OCc1c2ccccc2cc2ccccc12)n1ccnc1 ; CC(=O)O/N=C(\C(=O)c1ccc(Sc2ccccc2)cc1)c1ccccc1C ; CCN(CC)C(=O)/C=C/c1ccc(OC)cc1]

### [Preparation of Polybenzoxazole Precursor]

A polybenzoxazole precursor was prepared according to the following method. Regarding the preparation method of a polybenzoxazole precursor, a reaction between aromatic diaminediol and an dialdehyde compound (DC1), and a reaction between aromatic diaminediol and dicarboxylic acid dihalide (DC2) are described below.

### (Reaction Between Aromatic Diaminediol and Dialdehyde Compound)

After an aromatic diaminediol of the type and the amount described in Table 1 and a solvent of the type and the amount described in Table 1 were put into an Erlenmeyer flask containing a rotor, the content in the flask was stirred for 5 minutes using a magnetic stirrer. Thereafter, DC1 (isophthalaldehyde) of the amount shown in Table 1 was put into the flask, and the content in the flask was refluxed for 3 hours in a nitrogen atmosphere to proceed a reaction. Next, the reaction liquid was dehydrated by distillation under reduced pressure, whereby a solution of a polybenzoxazole precursor was obtained. As an example, in Example 4, the number average molecular weight of the polybenzoxazole precursor was about 1500.

### (Reaction Between Aromatic Diaminediol and Dicarboxylic Acid Dihalide)

An aromatic diaminediol of the type and the amount described in Table 1, triethylamine in a molar amount twice as much as that of the aromatic diaminediol and the solvent (the amount is half of the amount described in Table 1) of the type described in Table 1 were put into an Erlenmeyer flask containing a rotor. Next, a solution obtained by dissolving DC2 (terephthalic acid dichloride) of the amount described in Table 1 in the solvent of the type described in Table 1 (the amount is half of the amount described in Table 1) was added dropwise to the Erlenmeyer flask at 0° C. over a period of 30 minutes in a nitrogen atmosphere. After the dropping ended, the reaction liquid in the Erlenmeyer flask was further stirred at room temperature for 5 hours, whereby a solution of a polybenzoxazole precursor was obtained.

### [Preparation of Energy-Sensitive Resin Composition]

Any one of the compounds E1 to E5 and the comparative compound C1 was added in the amount described in Table 1 to the solution of the polybenzoxazole precursor obtained in each of examples and comparative examples, and the resulting product was stirred, whereby an energy-sensitive resin composition was prepared.

### [Preparation and Evaluation of Polybenzoxazole Resin Film]

A polybenzoxazole resin film was formed by using the energy-sensitive resin composition obtained in each of examples and comparative examples according to the following method, and the tensile elongation, film forming properties, chemical resistance (NMP), coloring, and patterning characteristics of the polybenzoxazole resin film were evaluated. The evaluation results thereof are described in Table 1.

### (Evaluation of Tensile Elongation)

The obtained energy-sensitive resin composition was applied to a wafer substrate using an applicator (manufactured by YOSHIMITSU SEIKI Co., TBA-7 type). The coating film on the wafer substrate was heated under the conditions described in Table 1, whereby a polybenzoxazole resin film having a film thickness of about 10 μm was formed. Dumbbell-shaped test pieces having a shape conforming to the IEC450 standard were punched out from the obtained polybenzoxazole resin film, whereby test pieces for measuring tensile elongation were obtained. Using the obtained test piece, the breaking elongation of the polybenzoxazole resin was measured using a universal testing machine (TENSILON, manufactured by Orientech Co., Ltd.) under the conditions of a distance between chucks of 20 mm and an elastic stress rate of 2 mm/min. A case where the breaking elongation was 30% or greater was evaluated as B, a case where the breaking elongation was 25% or greater and less than 30% was evaluated as C, and a case where the breaking elongation was less than 25% was evaluated as D.

### (Evaluation of Film Forming Properties)

A polybenzoxazole resin film having a film thickness of about 10 μm was formed in the same manner as in the evaluation of tensile elongation. The obtained polybenzoxazole resin film was visually observed, and a case where defects such as blister, crack, and foam were hardly observed in the polyimide film or these defects were observed within a range of about 20% or less of the total area of the polyimide film was evaluated as B, a case where these defects were observed within a range of greater than about 20% and about 30% or less of the total area of the polyimide film was evaluated as C, and a case where these defects were observed within a range of greater than about 30% of the total area of the polyimide film was evaluated as D.

(Evaluation of chemical resistance)

A polybenzoxazole resin film having a film thickness of about 10 μm was formed in the same manner as in the evaluation of tensile elongation. 1 cc of NMP was dropped onto the formed film, then, the resulting product was left to stand for 1 minute or 2 minutes, and the NMP was removed. The surface state of the film after the NMP was removed was visually observed, and a case where even when left to stand for 2 minutes, there was no change on the film surface was evaluated as B, a case where when left to stand for 2 minutes, marks such as a pit remained on the film surface, but when left to stand for 1 minute, there was no change on the film surface was evaluated as C, and a case where even when left to stand 1 minute, marks such as a pit remained on the film surface was evaluated as D.

### (Evaluation of Coloring)

A polybenzoxazole resin film having a film thickness of about 10 μm was formed in the same manner as in the evaluation of tensile elongation. The total wavelength transmittance of the obtained polybenzoxazole resin film was measured using a spectrometer (trade name: MCPD-3000, manufactured by Otsuka Electronics Co., Ltd.). A case where the total wavelength transmittance was 95% or greater was evaluated as A, a case where the total wavelength transmittance was 90% or greater and less than 95% was evaluated as B, a case where the total wavelength transmittance was 80% or greater and less than 90% was evaluated as C, and a case where the total wavelength transmittance was less than 80% was evaluated as D.

### (Evaluation of Patterning Characteristics)

The obtained energy-sensitive resin composition was applied to a wafer substrate using a spin coater (manufactured by MIKASA CO., LTD, 1H-360S), and the resulting product was prebaked at 80° C. for 5 minutes, whereby a coating film having a film thickness of 3 μm was formed. Using a mask of a line-and-space pattern, the coating film was exposed with a high-pressure mercury lamp under the condition of 100 mJ/cm². The exposed coating film was heated on a hot plate at 120° C. for 5 minutes, and immersed in a developing solution (a solution obtained by mixing a 2.38% by mass aqueous solution of tetramethylammonium hydroxide and isopropanol in a ratio of 9:1). As a result, it was possible to obtain a pattern in which the exposed portion remained without being dissolved in the developing solution. Next, by heating the developed coating film at 180° C. for 1 hour, conversion from a polybenzoxazole precursor to a polybenzoxazole resin was performed. The coating film after the conversion was observed, and the patterning characteristics were evaluated according to the following criteria. A case where a line having a width of 5 μm could be formed was evaluated as excellent (A), a case where a line having a width of 5 μm could not be formed, but a line having a width of 10 μm could be formed was evaluated as good (B), and a case where both a line having a width of 5 μm and a line having a width of 10 μm could not be formed evaluated as poor (D).

TABLE 1

| Material of energy-sensitive resin composition | | | | | | | | | |
|---|---|---|---|---|---|---|---|---|---|
| | | | Compound or | | | | | | |
| | | | comparative | | Evaluation of polybenzoxazole resin film | | | | |
| | | | compound | | | | | | Pat- |
| Aromatic | Dicarbonyl | | (type/g/ | | Tensile | Film | | | terning |
| diaminediol | compound | Solvent | decomposition | Baking | elon- | forming | Chemical | | charac- |
| (type/g) | (type/g) | (type/mL) | temperature) | conditions | gation | properties | resistance | Coloring | teristics |

Examples

| | | | | | | | | | | |
|---|---|---|---|---|---|---|---|---|---|---|
| 1 | DA1/0.73 | DC1/0.26 | NMP/1 | E1/0.1/130° C. | 180° C./20 min | B | B | B | A | B |
| 2 | DA2/0.43 | DC1/0.26 | NMP/1 | E1/0.1/130° C. | 180° C./20 min | B | B | B | A | B |
| 3 | DA2/0.43 | DC2/0.40 | NMP/1 | E1/0.1/130° C. | 180° C./20 min | B | B | B | A | B |
| 4 | DA1/0.73 | DC1/0.26 | TMU/1 | E1/0.1/130° C. | 180° C./20 min | B | B | B | A | B |
| 5 | DA2/0.43 | DC1/0.26 | TMU/1 | E1/0.1/130° C. | 180° C./20 min | B | B | B | A | B |
| 6 | DA2/0.43 | DC2/0.40 | TMU/1 | E1/0.1/130° C. | 180° C./20 min | B | B | B | A | B |
| 7 | DA1/0.73 | DC1/0.26 | DMIB/1 | E1/0.1/130° C. | 180° C./20 min | B | B | B | A | B |
| 8 | DA2/0.43 | DC1/0.26 | DMIB/1 | E1/0.1/130° C. | 180° C./20 min | B | B | B | A | B |
| 9 | DA2/0.43 | DC2/0.40 | DMIB/1 | E1/0.1/130° C. | 180° C./20 min | B | B | B | A | B |
| 10 | DA1/0.73 | DC1/0.26 | NMP/1 | E2/0.09/170° C. | 180° C./20 min | B | B | B | B | B |
| 11 | DA2/0.43 | DC1/0.26 | NMP/1 | E2/0.09/170° C. | 180° C./20 min | B | B | B | B | B |
| 12 | DA2/0.43 | DC2/0.40 | NMP/1 | E2/0.09/170° C. | 180° C./20 min | B | B | B | B | B |
| 13 | DA1/0.73 | DC1/0.26 | TMU/1 | E2/0.09/170° C. | 180° C./20 min | B | B | B | B | B |
| 14 | DA2/0.43 | DC1/0.26 | TMU/1 | E2/0.09/170° C. | 180° C./20 min | B | B | B | B | B |
| 15 | DA2/0.43 | DC2/0.40 | TMU/1 | E2/0.09/170° C. | 180° C./20 min | B | B | B | B | B |
| 16 | DA1/0.73 | DC1/0.26 | DMIB/1 | E2/0.09/170° C. | 180° C./20 min | B | B | B | B | B |
| 17 | DA2/0.43 | DC1/0.26 | DMIB/1 | E2/0.09/170° C. | 180° C./20 min | B | B | B | B | B |
| 18 | DA2/0.43 | DC2/0.40 | DMIB/1 | E2/0.09/170° C. | 180° C./20 min | B | B | B | B | B |
| 19 | DA1/0.73 | DC1/0.26 | NMP/1 | E3/0.10/130° C. | 180° C./20 min | B | B | B | A | B |
| 20 | DA1/0.73 | DC1/0.26 | NMP/1 | E4/0.07/130° C. | 180° C./20 min | B | B | B | A | B |
| 21 | DA1/0.73 | DC1/0.26 | NMP/1 | E5/0.08/130° C. | 180° C./20 min | B | B | B | A | B |
| 22 | DA1/0.73 | DC1/0.26 | NMP/1 | E1/0.1/130° C. | 180° C./20 min | B | B | B | A | A |
| | | | | E5/0.08/130° C. | | | | | | |
| 23 | DA1/0.73 | DC1/0.26 | NMP/1 | E2/0.18/170° C. | 180° C./20 min | B | B | B | C | B |
| 24 | DA1/0.73 | DC1/0.26 | NMP/1 | E5/0.16/130° C. | 180° C./20 min | B | B | B | A | B |

Comparative Examples

| | | | | | | | | | | |
|---|---|---|---|---|---|---|---|---|---|---|
| 1 | DA1/0.73 | DC1/0.26 | NMP/1 | None/0/— | 180° C./20 min | D | D | D | D | D |
| 2 | DA2/0.43 | DC1/0.26 | NMP/1 | None/0/— | 180° C./20 min | D | D | D | D | D |
| 3 | DA2/0.43 | DC2/0.40 | NMP/1 | None/0/— | 180° C./20 min | D | D | D | D | D |
| 4 | DA1/0.73 | DC1/0.26 | NMP/1 | C1/0.1/250° C. | 180° C./20 min | D | D | D | D | B |
| 5 | DA1/0.73 | DC1/0.26 | TMU/1 | None/0/— | 180° C./20 min | C | C | C | B | D |

According to Examples 1 to 24, it is found that by adding a compound (A-1) which decomposes by the action of at least one of light and heat to generate an imidazole compound (in particular, a compound represented by the formula (4) or (6)) or an oxime compound (A-2) (in particular, a compound represented by the formula (D1)), a polybenzoxazole resin which has excellent mechanical characteristics such as tensile elongation and excellent chemical resistance, high transparency with suppressed coloring, and good patterning characteristics is obtained from an energy-sensitive resin composition containing a polybenzoxazole precursor even in a case where a thermal treatment is performed at a low temperature of 180° C. In addition, according to the results of the test of film forming properties for Examples 1 to 24, it is found that by thermally treating a thin film formed of an energy-sensitive resin composition including the compound (A-1) or (A-2), a polybenzoxazole resin film without defects such as blister, crack, and pinholes can be obtained. The compounds E1 to E5 used in Examples 1 to 24 correspond to compounds which decompose at 120° C. to 180° C. and generate a base.

According to Comparative Examples 1 to 3, it is found that in a case where N-methyl-2-pyrrolidone is used as a solvent and the compounds E1 to E5 are not added, there is a tendency that mechanical characteristics such as tensile elongation, chemical resistance, and patterning characteristics are poor, and transparency is reduced since coloring is not suppressed, and thus, a polybenzoxazole resin film without defects such as blister, crack, and pinholes is less likely to be obtained.

According to Comparative Example 5, it is found that in a case where N,N,N′,N′-tetramethylurea is used as a solvent and the compounds E1 to E5 are not added, there is a tendency that although transparency is improved with suppressed coloring, mechanical characteristics such as tensile elongation and chemical resistance are slightly poor, and patterning characteristics are poor, and thus, a polybenzoxazole resin film without defects such as blister, crack, and pinholes is slightly less likely to be obtained.

According to Comparative Example 4, it is found that in a case where the comparative compound C1 which decomposes by the action of light or heat but does not generate an imidazole compound is used, there is a tendency that although patterning characteristics are good, mechanical characteristics such as tensile elongation and chemical resistance are poor, and transparency is reduced since coloring is not suppressed, and thus, a polybenzoxazole resin film without defects such as blister, crack, and pinholes is less likely to be obtained. The comparative compound C1 used in Comparative Example 4 is a compound which decomposes at a high temperature of 250° C. to generate a base.

What is claimed is:

1. An energy-sensitive resin composition, comprising:
a polybenzoxazole precursor obtained by reacting an aromatic diaminediol represented by the following formula (1) with a dicarbonyl compound represented by the following formula (2);
a solvent; and
a compound (A) which decomposes by the action of at least one of light and heat to generate at least one of a base and an acid: 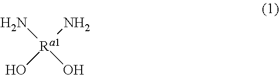
wherein R^{a1} is a tetravalent organic group containing one or more aromatic rings, and with respect to two pairs of combinations of an amino group and a hydroxyl group contained in the aromatic diaminediol represented by the formula (1), the amino group and the hydroxyl group in each of the combinations are bonded to two carbon atoms adjacent to each other on the aromatic ring contained in R^{a1}; 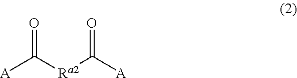
wherein R^{a2} represents a divalent organic group, and A represents a hydrogen atom or a halogen atom.

2. The energy-sensitive resin composition according to claim 1,
wherein the compound (A) includes a compound (A-1) which decomposes by the action of at least one of light and heat to generate an imidazole compound, and at least one oxime compound (A-2).

3. The energy-sensitive resin composition according to claim 2, wherein the compound (A-1) is a compound which generates an imidazole compound represented by the following formula (3): 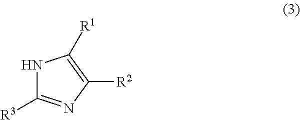
wherein R¹, R², and R³ each independently represents a hydrogen atom, a halogen atom, a hydroxyl group, a mercapto group, a sulfide group, a silyl group, a silanol group, a nitro group, a nitroso group, a sulfonato group, a phosphino group, a phosphinyl group, a phosphonato group, or an organic group.

4. The energy-sensitive resin composition according to claim 2, wherein the compound (A-1) is a compound represented by the following formula (4): 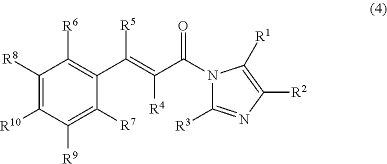
wherein R¹, R², and R³ each independently represents a hydrogen atom, a halogen atom, a hydroxyl group, a mercapto group, a sulfide group, a silyl group, a silanol group, a nitro group, a nitroso group, a phosphino group, a sulfonato group, a phosphinyl group, a phosphonato group, or an organic group; R⁴ and R⁵ each independently represent a hydrogen atom, a halogen atom, a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, or an organic group; R⁶, R⁷, R⁸, R⁹, and R¹⁰ each independently represent a hydrogen atom, a halogen atom, a hydroxyl group, a mercapto group, a sulfide group, a silyl group, a silanol group, a nitro group, a nitroso group, a sulfino group, a sulfo group, a sulfonato group, a phosphino group, a phosphinyl group, a phosphono group, a phosphonato group, an amino group, an ammonio group, or an organic group; and two or more of R⁶, R⁷, R⁸, R⁹, and R¹⁰ may join together to form a cyclic structure, which may include a bond of a hetero atom.

5. The energy-sensitive resin composition according to claim 1, wherein the compound (A) is a compound which decomposes at 120° C. to 180° C. to generate a base.

6. The energy-sensitive resin composition according to claim 1, wherein the compound (A) is a compound which decomposes by the action of light at least to generate at least one of a base and an acid.

7. A method for producing a polybenzoxazole film or a polybenzoxazole molded product, comprising:
forming a coating film or a molded product formed of the energy-sensitive resin composition according to claim 1; and
decomposing a compound (A) in the coating film or the molded product by exposing or heating the coating film or the molded product.

8. A pattern forming method, comprising:
forming a coating film or a molded product formed of the energy-sensitive resin composition according to claim 6;
selectively exposing the coating film or the molded product;
developing the coating film or the molded product after the exposing; and
heating the coating film or the molded product after the developing.
